(19) United States
(12) Patent Application Publication
(10) Pub. No.: US 2026/0238407 A1
(43) Pub. Date: Aug. 13, 2026

(54) A HYBRID CONSTRUCTION OF A POLARIZATION-ADJUSTED CONVOLUTIONAL CODE FOR WIRELESS COMMUNICATION

(71) Applicant: QUALCOMM Incorporated, San Diego, CA (US)

(72) Inventors: Jian LI, Shanghai (CN); Liangming WU, Beijing (CN); Changlong XU, Beijing (CN); Kangqi LIU, San Diego, CA (US); Wei LIU, Beijing (CN); Kexin XIAO, Shanghai (CN); Ruiming ZHENG, Beijing (CN); Hao XU, Beijing (CN)

(21) Appl. No.: 19/155,880

(22) PCT Filed: Mar. 25, 2023
(86) PCT No.: PCT/CN2023/083910

§ 371 Date: Aug. 12, 2025

(51) Int. Cl. H04L 5/00; H04W 72/044

(52) U.S. Cl. CPC H04L 5/0023; H04W 72/044

(57) ABSTRACT

This disclosure provides methods, components, devices and systems for hybrid constructions of a polarization-adjusted convolutional (PAC) code. Some aspects more specifically relate to mechanisms according to which wireless communication devices may encode and/or decode wireless communications in accordance with a hybrid construction of a PAC code. Such a hybrid construction of a PAC code may be a weighted Gaussian approximation (GA)- and Reed-Muller (RM)-based construction of a PAC code. In some implementations, the hybrid construction may be associated with weighted sums of GA-based sub-channel polarization weights and RM-based sub-channel polarization weights. In some other implementations, the hybrid construction may be associated with weighted sums of indexes of a GA-based sequence and indexes of an RM-based sequence. A wireless communication device may calculate a set of weighted metrics in accordance with the weighted sums and encode or decode a set of information bits in accordance with the set of weighted metrics.

### CROSS REFERENCE

The present application is a 371 national phase filing of International PCT Application No. PCT/CN2023/083910 by LI et al., entitled “A HYBRID CONSTRUCTION OF A POLARIZATION-ADJUSTED CONVOLUTIONAL CODE FOR WIRELESS COMMUNICATION,” filed Mar. 25, 2023, which is assigned to the assignee hereof, and which is expressly incorporated by reference in its entirety herein.

### TECHNICAL FIELD

The following relates to wireless communication, including a hybrid construction of a polarization-adjusted convolutional (PAC) code for wireless communication.

### DESCRIPTION OF THE RELATED TECHNOLOGY

Wireless communication systems are widely deployed to provide various types of communication content such as voice, video, packet data, messaging, broadcast, and so on. These systems may be capable of supporting communication with multiple users by sharing the available system resources (such as time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communication system may include one or more base stations, each supporting wireless communication for communication devices, which may be known as user equipment (UE).

Wireless communication devices may encode and/or decode over-the-air (OTA) signaling in accordance with various types of codes. In some systems, for example, wireless communication devices may encode and/or decode OTA signaling in accordance with a type of Polar code, such as a polarization-adjusted convolutional (PAC) code. A baseline Polar code may be associated with a polar transform and a PAC code may be associated with an outer convolutional coding block in front of the polar transform, which may avoid a fixing of a bit channel input to prevent capacity loss for some code lengths. Wireless communication devices communicating in accordance with PAC code may experience greater performance as compared to other types of Polar code for some, but not all, code lengths. More specifically, the PAC code may be constructed to provide relatively greater performance for OTA message encoding and/or decoding associated with a first code length, but may otherwise provide relatively poorer performance for OTA message encoding and/or decoding associated with other code lengths. For example, the PAC code may provide relatively greater performance for OTA messages having a code length of N=128 and relatively poorer performance for OTA messages having other code lengths, such as code lengths of N=256 and/or N=512.

### SUMMARY

The systems, methods and devices of this disclosure each have several innovative aspects, no single one of which is solely responsible for the desirable attributes disclosed herein.

One innovative aspect of the subject matter described in this disclosure can be implemented in a method for wireless communication at a wireless communication device. The method may include encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value and transmitting, via a set of sub-channels including at least some of the set of multiple sub-channels, a message in accordance with encoding the set of information bits in accordance with the set of multiple weighted metrics.

Another innovative aspect of the subject matter described in this disclosure can be implemented in an apparatus for wireless communication at a wireless communication device. The apparatus may include a processor, memory coupled with the processor, and instructions stored in the memory. The instructions may be executable by the processor to cause the apparatus to encode a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value and transmit, via a set of sub-channels including at least some of the set of multiple sub-channels, a message in accordance with encoding the set of information bits in accordance with the set of multiple weighted metrics.

Another innovative aspect of the subject matter described in this disclosure can be implemented in an apparatus for wireless communication at a wireless communication device. The apparatus may include means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value and means for transmitting, via a set of sub-channels including at least some of the set of multiple sub-channels, a message in accordance with encoding the set of information bits in accordance with the set of multiple weighted metrics.

Another innovative aspect of the subject matter described in this disclosure can be implemented in a non-transitory computer-readable medium storing code for wireless communication at a wireless communication device. The code may include instructions executable by a processor to encode a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value and transmit, via a set of sub-channels including at least some of the set of multiple sub-channels, a message in accordance with encoding the set of information bits in accordance with the set of multiple weighted metrics.

Another innovative aspect of the subject matter described in this disclosure can be implemented in a method for wireless communication at a wireless communication device. The method may include encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value and transmitting, via a set of sub-channels including at least some of the set of multiple sub-channels, a message in accordance with encoding the set of information bits in accordance with the set of multiple weighted metrics.

Another innovative aspect of the subject matter described in this disclosure can be implemented in an apparatus for wireless communication at a wireless communication device. The apparatus may include a processor, memory coupled with the processor, and instructions stored in the memory. The instructions may be executable by the processor to cause the apparatus to encode a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value and transmit, via a set of sub-channels including at least some of the set of multiple sub-channels, a message in accordance with encoding the set of information bits in accordance with the set of multiple weighted metrics.

Another innovative aspect of the subject matter described in this disclosure can be implemented in an apparatus for wireless communication at a wireless communication device. The apparatus may include means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value and means for transmitting, via a set of sub-channels including at least some of the set of multiple sub-channels, a message in accordance with encoding the set of information bits in accordance with the set of multiple weighted metrics.

Another innovative aspect of the subject matter described in this disclosure can be implemented in a non-transitory computer-readable medium storing code for wireless communication at a wireless communication device. The code may include instructions executable by a processor to encode a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value and transmit, via a set of sub-channels including at least some of the set of multiple sub-channels, a message in accordance with encoding the set of information bits in accordance with the set of multiple weighted metrics.

Another innovative aspect of the subject matter described in this disclosure can be implemented in a method for wireless communication at a wireless communication device. The method may include receiving, via a set of sub-channels, a message and decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Another innovative aspect of the subject matter described in this disclosure can be implemented in an apparatus for wireless communication at a wireless communication device. The apparatus may include a processor, memory coupled with the processor, and instructions stored in the memory. The instructions may be executable by the processor to cause the apparatus to receive, via a set of sub-channels, a message and decode a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Another innovative aspect of the subject matter described in this disclosure can be implemented in an apparatus for wireless communication at a wireless communication device. The apparatus may include means for receiving, via a set of sub-channels, a message and means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Another innovative aspect of the subject matter described in this disclosure can be implemented in a non-transitory computer-readable medium storing code for wireless communication at a wireless communication device. The code may include instructions executable by a processor to receive, via a set of sub-channels, a message and decode a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Another innovative aspect of the subject matter described in this disclosure can be implemented in a method for wireless communication at a wireless communication device. The method may include receiving, via a set of sub-channels, a message and decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

Another innovative aspect of the subject matter described in this disclosure can be implemented in an apparatus for wireless communication at a wireless communication device. The apparatus may include a processor, memory coupled with the processor, and instructions stored in the memory. The instructions may be executable by the processor to cause the apparatus to receive, via a set of sub-channels, a message and decode a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

Another innovative aspect of the subject matter described in this disclosure can be implemented in an apparatus for wireless communication at a wireless communication device. The apparatus may include means for receiving, via a set of sub-channels, a message and means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

Another innovative aspect of the subject matter described in this disclosure can be implemented in a non-transitory computer-readable medium storing code for wireless communication at a wireless communication device. The code may include instructions executable by a processor to receive, via a set of sub-channels, a message and decode a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an example wireless communication system that supports a hybrid construction of a polarization-adjusted convolutional (PAC) code for wireless communication.

FIGS. 2 and 3 show example encoding and signaling mechanisms that support a hybrid construction of a PAC code for wireless communication.

FIGS. 4 and 5 show block diagrams of devices that support a hybrid construction of a PAC code for wireless communication.

FIG. 6 shows a block diagram of a communication manager that supports a hybrid construction of a PAC code for wireless communication.

FIG. 7 shows a diagram of a system including a UE that supports a hybrid construction of a PAC code for wireless communication.

FIG. 8 shows a diagram of a system including a network entity that supports a hybrid construction of a PAC code for wireless communication.

FIGS. 9-12 show flowcharts illustrating methods that support a hybrid construction of a PAC code for wireless communication.

Like reference numbers and designations in the various drawings indicate like elements.

### DETAILED DESCRIPTION

The following description is directed to some particular examples for the purposes of describing innovative aspects of this disclosure. However, a person having ordinary skill in the art will readily recognize that the teachings herein can be applied in a multitude of different ways. Some or all of the described examples may be implemented in any device, system or network that is capable of transmitting and receiving radio frequency (RF) signals according to one or more of the Institute of Electrical and Electronics Engineers (IEEE) 802.11 standards, the IEEE 802.15 standards, the Bluetooth® standards as defined by the Bluetooth Special Interest Group (SIG), or the Long Term Evolution (LTE), 3G, 4G or 5G (New Radio (NR)) standards promulgated by the 3rd Generation Partnership Project (3GPP), among others. The described examples can be implemented in any device, system or network that is capable of transmitting and receiving RF signals according to one or more of the following technologies or techniques: code division multiple access (CDMA), time division multiple access (TDMA), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple-input multiple-output (MIMO) and multi-user (MU)-MIMO. The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), or an internet of things (IOT) network.

Various aspects relate generally to one or more hybrid constructions of a polarization-adjusted convolutional (PAC) code, and more specifically, to mechanisms according to which wireless communication devices may encode and/or decode wireless communications in accordance with a hybrid construction of a PAC code. Such a hybrid construction of a PAC code may be a weighted Gaussian approximation (GA)- and Reed-Muller (RM)-based construction. In some examples, the hybrid construction may be associated with weighted sums of GA-based sub-channel polarization weights and RM-based sub-channel polarization weights. In some other examples, the hybrid construction may be associated with weighted sums of indexes of a GA-based sequence and indexes of an RM-based sequence. A wireless communication device may determine (such as calculate, select, identify, or otherwise determine) a set of weighted metrics in accordance with the weighted sums (of either the GA-based sub-channel polarization weights and the RM-based sub-channel polarization weights or the indexes of the GA-based sequence and the indexes of the RM-based sequence) and may encode and/or decode a set of information bits in accordance with the set of weighted metrics. The wireless communication device may determine (for example, calculate) the set of weighted metrics in accordance with a scaling value, which the wireless communication device may select from a set of multiple available scaling values in accordance with a quantity of information bits to be encoded and/or decoded. In some implementations, the wireless communication device or a manufacturer of the wireless communication device may select (such as pre-select) a correspondence between the multiple available scaling values and quantities of information bits in accordance with a simulation (such as an offline search or simulation) and/or other metrics (such as historical metrics). In some aspects, each respective weighted metric of the set of weighted metrics may be associated with a respective sub-channel of a set of sub-channels, and the wireless communication device may communicate (for example, transmit and/or receive) a data message associated with the set of information bits via at least a subset of the set of sub-channels.

Particular aspects of the subject matter described in this disclosure can be implemented to realize one or more of the following potential advantages. In some implementations, by encoding or decoding wireless communications in accordance with a hybrid construction of a PAC code, the described techniques can be used to achieve greater performance for diverse code lengths compared to other coding techniques through adapting a relative weighting of a GA-based construction and an RM-based construction in accordance with code length. For example, while some other types of Polar codes may be specifically adapted to a specific code length (such as a code length of N=128), the described hybrid construction of a PAC code may dynamically and flexibly adapt to a wide range of code lengths (such as code lengths of N=128, N=256, N=512, and so on) by supporting an “on-the-fly” adjustable weighting between the GA-based construction and the RM-based construction depending on a specific code length to be encoded or decoded. Such greater performance may include a relatively greater signal-to-noise ratio (SNR) or a relatively lower block error rate (BLER), or both, at the wireless communication device because the adjustable weighting of the hybrid construction may be tailored for relatively more emphasis on a use of a set of highest reliability sub-channels or relatively more emphasis on a use of a set of largest weight sub-channels depending on channel conditions and target throughput, among other examples. In accordance with such greater SNRs or lower BLERs, the wireless communication device may experience higher reliability, which may, in turn, facilitate higher data rates, greater capacity, and greater spectral efficiency, among other benefits. Further, by pre-selecting a correspondence between a scaling value and a quantity of information bits in accordance with a simulation or other metrics, the wireless communication device may save (such as store) one scaling value for each code length, which may be associated with low storage or memory costs at the wireless communication device by avoiding a need to again perform selection of the correspondence between the scaling value and the quantity of information bits.

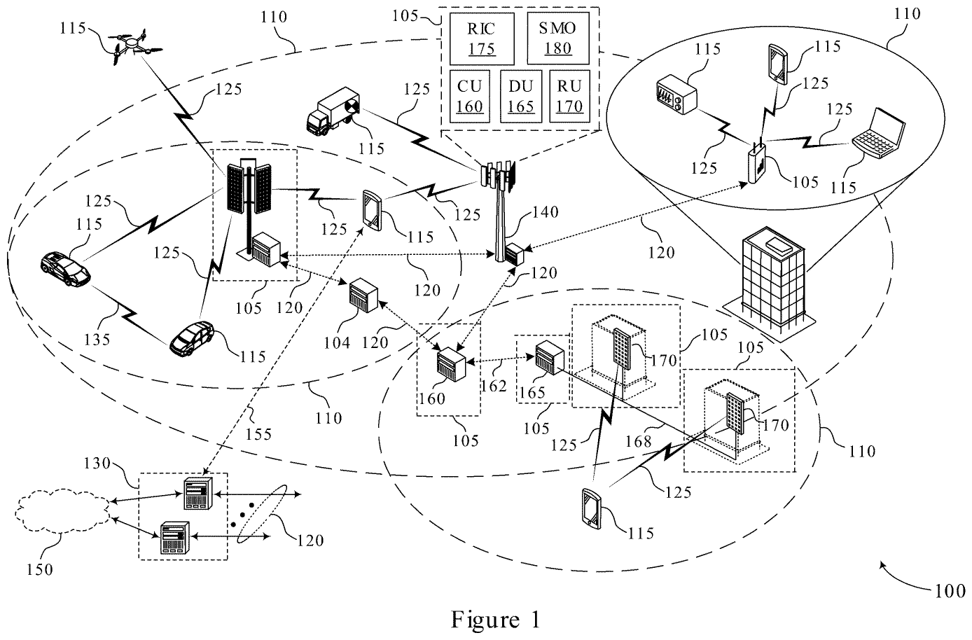

FIG. 1 shows an example of a wireless communication system 100 that supports a hybrid construction of a PAC code for wireless communication. The wireless communication system 100 may include one or more network entities 105, one or more UEs 115, and a core network 130. In some implementations, the wireless communication system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communication system 100 and may include devices in different forms or having different capabilities. In various examples, a network entity 105 may be referred to as a network element, a mobility element, a radio access network (RAN) node, or network equipment, among other nomenclature. In some implementations, network entities 105 and UEs 115 may wirelessly communicate via one or more communication links 125 (such as a radio frequency (RF) access link). For example, a network entity 105 may support a coverage area 110 (such as a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communication system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communication with various types of devices, such as other UEs 115 or network entities 105, as shown in FIG. 1.

A node of the wireless communication system 100, which may be referred to as a network node, or a wireless node, may be a network entity 105 (such as any network entity described herein), a UE 115 (such as any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, or a computing system, among other examples, may include disclosure of the UE 115, network entity 105, apparatus, device, or the computing system, among other examples, being a node. For example, disclosure that a UE 115 is configured to receive information from a network entity 105 also discloses that a first node is configured to receive information from a second node.

In some implementations, network entities 105 may communicate with the core network 130, or with one another, or both. For example, network entities 105 may communicate with the core network 130 via one or more backhaul communication links 120 (such as in accordance with an S1, N2, N3, or other interface protocol). In some implementations, network entities 105 may communicate with one another via a backhaul communication link 120 (such as in accordance with an X2, Xn, or other interface protocol) either directly (such as directly between network entities 105) or indirectly (such as via a core network 130). In some implementations, network entities 105 may communicate with one another via a midhaul communication link 162 (such as in accordance with a midhaul interface protocol) or a fronthaul communication link 168 (such as in accordance with a fronthaul interface protocol), or any combination thereof. The backhaul communication links 120, midhaul communication links 162, or fronthaul communication links 168 may be or include one or more wired links (such as an electrical link, an optical fiber link), one or more wireless links (such as a radio link, a wireless optical link), among other examples or various combinations thereof. A UE 115 may communicate with the core network 130 via a communication link 155.

One or more of the network entities 105 described herein may include or may be referred to as a base station 140 (such as a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some implementations, a network entity 105 (such as a base station 140) may be implemented in an aggregated (such as monolithic, standalone) base station architecture, which may be configured to utilize a protocol stack that is physically or logically integrated within a single network entity 105 (such as a single RAN node, such as a base station 140).

In some implementations, a network entity 105 may be implemented in a disaggregated architecture (such as a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (such as a network configuration sponsored by the O-RAN Alliance), or a virtualized RAN (vRAN) (such as a cloud RAN (C-RAN)). For example, a network entity 105 may include one or more of a central unit (CU) 160, a distributed unit (DU) 165, a radio unit (RU) 170, a RAN Intelligent Controller (RIC) 175 (such as a Near-Real Time RIC (Near-RT RIC), a Non-Real Time RIC (Non-RT RIC)), a Service Management and Orchestration (SMO) 180 system, or any combination thereof. An RU 170 also may be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (such as separate physical locations). In some implementations, one or more network entities 105 of a disaggregated RAN architecture may be implemented as virtual units (such as a virtual CU (VCU), a virtual DU (VDU), a virtual RU (VRU)).

The split of functionality between a CU 160, a DU 165, and an RU 170 is flexible and may support different functionalities depending on which functions (such as network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some implementations, the CU 160 may host upper protocol layer (such as layer 3 (L3), layer 2 (L2)) functionality and signaling (such as Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (such as physical (PHY) layer) or L2 (such as radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (such as via one or more RUs 170). In some examples, a functional split between a CU 160 and a DU 165, or between a DU 165 and an RU 170 may be within a protocol layer (such as some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (such as F1, F1-c, F1-u), and a DU 165 may be connected to one or more RUs 170 via a fronthaul communication link 168 (such as open fronthaul (FH) interface). In some implementations, a midhaul communication link 162 or a fronthaul communication link 168 may be implemented in accordance with an interface (such as a channel) between layers of a protocol stack supported by respective network entities 105 that are in communication via such communication links.

In wireless communication systems (such as wireless communication system 100), infrastructure and spectral resources for radio access may support wireless backhaul link capabilities to supplement wired backhaul connections, providing an IAB network architecture (such as to a core network 130). In some examples, in an IAB network, one or more network entities 105 (such as IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (such as a donor base station 140). The one or more donor network entities 105 (such as IAB donors) may be in communication with one or more additional network entities 105 (such as IAB nodes 104) via supported access and backhaul links (such as backhaul communication links 120). IAB nodes 104 may include an IAB mobile termination (IAB-MT) controlled (such as scheduled) by DUs 165 of a coupled IAB donor. An IAB-MT may include an independent set of antennas for relay of communication with UEs 115, or may share the same antennas (such as of an RU 170) of an IAB node 104 used for access via the DU 165 of the IAB node 104 (such as referred to as virtual IAB-MT (vIAB-MT)). In some implementations, the IAB nodes 104 may include DUs 165 that support communication links with additional entities (such as IAB nodes 104, UEs 115) within the relay chain or configuration of the access network (such as downstream). In such implementations, one or more components of the disaggregated RAN architecture (such as one or more IAB nodes 104 or components of IAB nodes 104) may be configured to operate according to the techniques described herein.

In the case of the techniques described herein applied in the context of a disaggregated RAN architecture, one or more components of the disaggregated RAN architecture may be configured to support a hybrid construction of a PAC code for wireless communication. For example, some operations described as being performed by a UE 115 or a network entity 105 (such as a base station 140) may additionally, or alternatively, be performed by one or more components of the disaggregated RAN architecture (such as IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology. In some examples, the “device” also may be referred to as a unit, a station, a terminal, or a client, among other examples. A UE 115 also may include or may be referred to as a personal electronic device such as a cellular phone, a personal digital assistant (PDA), a tablet computer, a laptop computer, or a personal computer. In some implementations, a UE 115 may include or be referred to as a wireless local loop (WLL) station, an Internet of Things (IoT) device, an Internet of Everything (IoE) device, or a machine type communication (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (such as an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (such as a bandwidth part (BWP)) that is operated according to one or more physical layer channels for a given radio access technology (such as LTE, LTE-A, LTE-A Pro, NR). Each physical layer channel may carry acquisition signaling (such as synchronization signals, system information), control signaling that coordinates operation for the carrier, user data, or other signaling. The wireless communication system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (such as entity, sub-entity) of a network entity 105. For example, the terms “transmitting,” “receiving,” or “communicating,” when referring to a network entity 105, may refer to any portion of a network entity 105 (such as a base station 140, a CU 160, a DU 165, a RU 170) of a RAN communicating with another device (such as directly or via one or more other network entities 105).

Signal waveforms transmitted via a carrier may be made up of multiple subcarriers (such as using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (such as a duration of one modulation symbol) and one subcarrier, in which case the symbol period and subcarrier spacing may be inversely related. The quantity of bits carried by each resource element may depend on the modulation scheme (such as the order of the modulation scheme, the coding rate of the modulation scheme, or both), such that a relatively higher quantity of resource elements (such as in a transmission duration) and a relatively higher order of a modulation scheme may correspond to a relatively higher rate of communication. A wireless communication resource may refer to a combination of an RF spectrum resource, a time resource, and a spatial resource (such as a spatial layer, a beam), and the use of multiple spatial resources may increase the data rate or data integrity for communication with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communication resource may be organized according to radio frames each having a specified duration (such as 10 milliseconds (ms)). Each radio frame may be identified by a system frame number (SFN) (such as ranging from 0 to 1023).

Each frame may include multiple consecutively-numbered subframes or slots, and each subframe or slot may have the same duration. In some implementations, a frame may be divided (such as in the time domain) into subframes, and each subframe may be further divided into a quantity of slots. Alternatively, each frame may include a variable quantity of slots, and the quantity of slots may depend on subcarrier spacing. Each slot may include a quantity of symbol periods (such as depending on the length of the cyclic prefix prepended to each symbol period). In some wireless communication systems 100, a slot may further be divided into multiple mini-slots associated with one or more symbols. Excluding the cyclic prefix, each symbol period may be associated with one or more (such as N_{f}) sampling periods. The duration of a symbol period may depend on the subcarrier spacing or frequency band of operation.

A subframe, a slot, a mini-slot, or a symbol may be the smallest scheduling unit (such as in the time domain) of the wireless communication system 100 and may be referred to as a transmission time interval (TTI). In some implementations, the TTI duration (such as a quantity of symbol periods in a TTI) may be variable. Additionally, or alternatively, the smallest scheduling unit of the wireless communication system 100 may be dynamically selected (such as in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (such as a control resource set (CORESET)) for a physical control channel may be defined by a set of symbol periods and may extend across the system bandwidth or a subset of the system bandwidth of the carrier. One or more control regions (such as CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (such as control channel elements (CCEs)) associated with encoded information for a control information format having a given payload size. Search space sets may include common search space sets configured for sending control information to multiple UEs 115 and UE-specific search space sets for sending control information to a specific UE 115.

In some implementations, a network entity 105 (such as a base station 140, an RU 170) may be movable and therefore provide communication coverage for a moving coverage area 110. In some implementations, different coverage areas 110 associated with different technologies may overlap, but the different coverage areas 110 may be supported by the same network entity 105. In some other examples, the overlapping coverage areas 110 associated with different technologies may be supported by different network entities 105. The wireless communication system 100 may include, for example, a heterogeneous network in which different types of the network entities 105 provide coverage for various coverage areas 110 using the same or different radio access technologies.

The wireless communication system 100 may be configured to support ultra-reliable communication or low-latency communication, or various combinations thereof. For example, the wireless communication system 100 may be configured to support ultra-reliable low-latency communication (URLLC). The UEs 115 may be designed to support ultra-reliable, low-latency, or critical functions. Ultra-reliable communication may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some implementations, a UE 115 may be configured to support communicating directly with other UEs 115 via a device-to-device (D2D) communication link 135 (such as in accordance with a peer-to-peer (P2P), D2D, or sidelink protocol). In some implementations, one or more UEs 115 of a group that are performing D2D communication may be within the coverage area 110 of a network entity 105 (such as a base station 140, an RU 170), which may support aspects of such D2D communication being configured by (such as scheduled by) the network entity 105. In some implementations, one or more UEs 115 of such a group may be outside the coverage area 110 of a network entity 105 or may be otherwise unable to or not configured to receive transmissions from a network entity 105. In some implementations, groups of the UEs 115 communicating via D2D communication may support a one-to-many (1:M) system in which each UE 115 transmits to each of the other UEs 115 in the group. In some implementations, a network entity 105 may facilitate the scheduling of resources for D2D communication. In some other examples, D2D communication may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (such as a mobility management entity (MME), an access and mobility management function (AMF)) and at least one user plane entity that routes packets or interconnects to external networks (such as a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (such as base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communication system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communication using UHF waves may be associated with smaller antennas and shorter ranges (such as less than 100 kilometers) compared to communication using the smaller frequencies and longer waves of the high frequency (HF) or very high frequency (VHF) portion of the spectrum below 300 MHz.

The wireless communication system 100 may utilize both licensed and unlicensed RF spectrum bands. For example, the wireless communication system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some implementations, operations using unlicensed bands may be based on a carrier aggregation configuration in conjunction with component carriers operating using a licensed band (such as LAA). Operations using unlicensed spectrum may include downlink transmissions, uplink transmissions, P2P transmissions, or D2D transmissions, among other examples.

A network entity 105 (such as a base station 140, an RU 170) or a UE 115 may be equipped with multiple antennas, which may be used to employ techniques such as transmit diversity, receive diversity, multiple-input multiple-output (MIMO) communication, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some implementations, antennas or antenna arrays associated with a network entity 105 may be located at diverse geographic locations. A network entity 105 may include an antenna array with a set of rows and columns of antenna ports that the network entity 105 may use to support beamforming of communication with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which also may be referred to as spatial filtering, directional transmission, or directional reception, is a signal processing technique that may be used at a transmitting device or a receiving device (such as a network entity 105, a UE 115) to shape or steer an antenna beam (such as a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (such as with respect to the antenna array of the transmitting device or receiving device, or with respect to some other orientation).

In some systems, wireless communication devices may encode and/or decode over-the-air (OTA) signaling (including control or data messages sent via control or shared channels) in accordance with various types of code or coding techniques (which may be equivalently referred to as coding mechanisms). In some systems, for example, wireless communication devices may encode and/or decode OTA signaling in accordance with a Polar code. For example, a wireless communication device (such as a UE 115 or a network entity 105) may employ Polar code for encoding and/or decoding information associated with a control channel (such as a 5GNR control channel).

A wireless communication device may employ (such as encode and/or decode in accordance with) a specific type of Polar code. For example, in some systems, a wireless communication device may employ PAC code, which may be associated with a rate profiling, a convolution, and a Polar transform. In examples in which a wireless communication device encodes and/or decodes in accordance with a PAC code, the wireless communication device may apply rate profiling to an information bit d (which may be equivalently referred to or understood as a source word) to obtain a data carrier word v and may apply a convolution (such as a rate-1 convolutional encode) to the data carrier word v to obtain a codeword u. The wireless communication device may use the codeword u as an input to a Polar code (such as a first generation or conventional Polar code) to obtain a PAC codeword x for transmission via a wireless channel.

To obtain the PAC codeword x from the data carrier word v, a wireless communication device may calculate, compute, or otherwise perform processing operations associated with x=vTPₙ. In some examples, T may be a convolution operation (such as a pre-transformed matrix) and Pₙ may be a polar transform. Additionally, or alternatively, to obtain the PAC codeword x from the data carrier word v, a wireless communication device may calculate, compute, or otherwise perform processing operations associated with u=vT and x=uPₙ. Likewise, a first generation or conventional polar model may be associated with (such as defined by) X=U×F^{⊗n} and a PAC system model may be associated with (such as defined by) X=U×T×F^{⊗n}. In some aspects, block or code lengths for PAC codes may be powers of two, such that a quantity of information bits N (which may be equivalently understood or referred to as a quantity of bit channels) generally follows N=2ⁿ, n≥1. Further, in an example, a convolutional poly matrix (such as T) may be [1 1 0 1 0 1 1].

A mapping from data information (such as the information bit or source word d) to U may contribute meaningfully to performance and, in accordance with a PAC coding technique, a wireless communication device may use a GA-based construction mapping or an RM-based construction mapping. In accordance with such a PAC coding technique, a GA-based construction and an RM-based construction may be fixed. A wireless communication device may use a GA-based construction to select a K greatest reliability sub-channels or may use an RM-based construction to select a K largest weight sub-channels. In some aspects, GA may be associated with suitable or relatively high performance for cyclic redundancy check (CRC)-aided (CA)-Polar code, but may be less suitable for a PAC code. CA-Polar code may be associated with various CRC sizes, such as CRC sizes of 6, 8, and 11.

Such fixed GA-based or RM-based constructions may facilitate greater performance as compared to other types of Polar code for some, but not all, code lengths. For example, PAC code may be constructed to provide relatively greater (such as peak) performance for OTA messages associated with a first code length, but may otherwise provide relatively poorer performance. For example, a PAC code may provide relatively greater (such as peak) performance for scenarios of code length N=128 and code dimension K=64 code and may provide relatively poorer performance for other code lengths, such as code lengths of N=256 (such as with a code dimension K=128) or N=512 (such as with a code dimension K=256). A wireless communication device may measure such changes in performance across various list decoder list sizes (such as for a list decoder with a list size of 8, 16, 32, 64, or 128). In other words, some PAC constructions may not be universally better for all code lengths (and more specifically, may be relatively poorly suited for code lengths outside of N=128).

In some implementations, a wireless communication device may support one or more mechanisms according to which the wireless communication device may encode and/or decode wireless communication in accordance with a hybrid construction of a PAC code. Such a hybrid construction of a PAC code may be a weighted GA- and RM-based construction of a PAC code. In some implementations, for example, the hybrid construction may be associated with weighted sums of GA-based sub-channel polarization weights and RM-based sub-channel polarization weights. In some other implementations, the hybrid construction may be associated with weighted sums of indexes of a GA-based sequence (such as a GA sequence) and indexes of an RM-based sequence (such as an RM sequence).

A wireless communication device may calculate (such as select, compute, identify, or otherwise determine) a set of weighted metrics in accordance with the weighted sums (of either the GA-based sub-channel polarization weights and the RM-based sub-channel polarization weights or the indexes of the GA-based sequence and the indexes of the RM-based sequence) and may encode or decode a set of information bits in accordance with the set of weighted metrics. In some implementations, the wireless communication device may calculate (such as select, compute, identify, or otherwise determine) the set of weighted metrics in accordance with a scaling value, which the wireless communication device may select from a set of multiple available scaling values in accordance with a quantity of information bits to be encoded or decoded.

In some implementations, the wireless communication device or a manufacturer may select (such as pre-select) a correspondence between scaling values and quantities of information bits in accordance with a simulation (such as offline search or simulation) or other metrics (such as historical metrics). For example, the wireless communication device may search for a set scaling values by simulation offline and may use (such as reference) a table (such as a lookup table stored in a memory of the wireless communication device) to select a scaling value from the set of scaling values. In some implementations, because a GM sequence and an RM sequence may be fixed (such as statically configured or generated), the wireless communication device may save one scaling value for a code length (such as one scaling value for each possible or available code length). A scaling value may be equivalently referred to or understood as a scaling factor, a scaling coefficient, a weighting coefficient, a weighting value, or a weighting factor. Further, example scaling values may include 0, 0.5, 1, 1.5, 2, and so on. In other words, scaling values may be integers or any rational numbers between 0 and an upper bound (which may be or approach infinity).

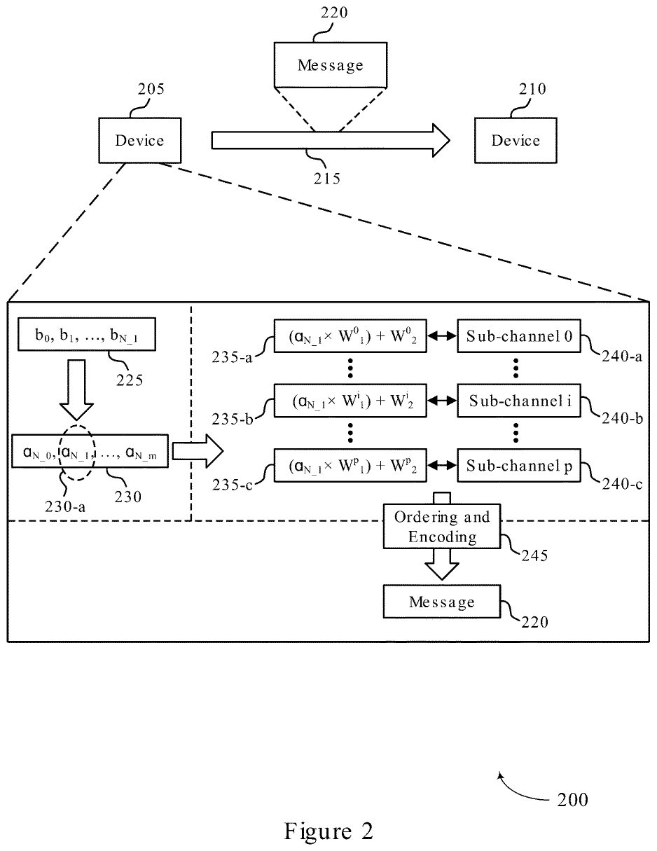

FIG. 2 shows an example encoding and signaling mechanism 200 that supports a hybrid construction of a PAC code for wireless communication. The encoding and signaling mechanism 200 may implement or be implemented to realize or facilitate aspects of the wireless communication system 100. For example, the encoding and signaling mechanism 200 illustrates wireless communication between a wireless communication device 205 and a wireless communication device 210, which may be examples of wireless communication devices as illustrated by and described with reference to FIG. 1. For example, the wireless communication device 205 and the wireless communication device 210 may be examples of a UE 115 or a network entity 105.

The wireless communication device 205 and the wireless communication device 210 may communicate with each other via a communication link 215 and, in some examples, the wireless communication device 205 may transmit a message 220 to the wireless communication device 210. In some implementations, the wireless communication device 205 and the wireless communication device 210 may communicate in accordance with a hybrid construction of a PAC code that is associated with weighted sums of two different sub-channel polarization weights. In other words, the encoding and signaling mechanism 200 may be associated with encoding and decoding in accordance with the weighted sums of the two different sub-channel polarization weights.

The wireless communication device 205 may select, identify, or otherwise ascertain a quantity of a set of information bits 225 that the wireless communication device 205 may transmit or otherwise convey via the message 220. As illustrated in the example of FIG. 2, the set of information bits 225 may include a quantity b_{N_1} information bits. In some implementations, the wireless communication device 205 may select a scaling value 230-a from a set of scaling values 230 in accordance with the quantity b_{N_1} information bits that are included in the set of information bits 225. As illustrated in the example of FIG. 2, the scaling value 230-a may be referred to as a scaling value a_{N_1}.

In some implementations, respective quantities of information bits b_{N} may correspond to respective scaling values a_{N} of the set of scaling values 230 in accordance with a mapping and the wireless communication device 205 may select the scaling value 230-a in accordance with the quantity b_{N_1} information bits and the mapping. Such an example mapping may be associated with a table with indexes (which may correspond to table entries) and the wireless communication device 205 may retrieve a given scaling value from the set of scaling values 230 by accessing or obtaining information from the table at a given index. In accordance with an example mapping, a scaling value a_{N_0} may correspond to a quantity b_{N_0} information bits, the scaling value a_{N_1} may correspond to the quantity b_{N_1} information bits, and a scaling value a_{N_m} may correspond to a quantity b_{N_m} information bits. In other words, the scaling value a_{N_0} may be associated with a first index of a table including the set of scaling values 230, the scaling value a_{N_1} may be associated with a second index of the table including the set of scaling values 230, and the scaling value a_{N_m} may be associated with an m^{th} index of the table including the set of scaling values 230.

In accordance with selecting the scaling value 230-a, the wireless communication device 205 may calculate (such as compute, select, identify, or otherwise determine) a set of weighted metrics 235 (including a weighted metric 235-a, a weighted metric 235-b, and a weighted metric 235-c) in accordance with a set of first sub-channel polarization weights, a set of second sub-channel polarization weights, and the scaling value 230-a. In some implementations, the wireless communication device 205 may calculate the set of weighted metrics 235 in accordance with scaling the set of first sub-channel polarization weights or the set of second sub-channel polarization weights by the scaling value 230-a and calculating weighted sums of the set of first sub-channel polarization weights and the set of second sub-channel polarization weight in accordance the scaling.

In examples in which the wireless communication device 205 scales the set of first sub-channel polarization weights by the scaling value 230-a, the wireless communication device 205 may calculate a weighted sum in accordance with a sum of a scaled (such as weighted) first sub-channel polarization weight and a (non-scaled or non-weighted) second sub-channel polarization weight. Alternatively, in examples in which the wireless communication device 205 scales the set of second sub-channel polarization weights by the scaling value 230-a, the wireless communication device 205 may calculate a weighted sum in accordance with a sum of a (non-scaled or non-weighted) first sub-channel polarization weight and a scaled (such as weighted) second sub-channel polarization weight. Additionally, or alternatively, the wireless communication device 205 may apply a first scaling value to the set of first sub-channel polarization weights and a second scaling value to the set of second sub-channel polarization weights and calculate a weighted sum in accordance with a scaled first sub-channel polarization weight and a scaled second sub-channel polarization weight.

The set of weighted metrics 235 may include a quantity p weighted metrics and each respective weighted metric of the set of weighted metrics 235 may be associated with (such as correspond to) a respective sub-channel of a set of sub-channels 240. For example, the weighted metric 235-a may be associated with a sub-channel 240-a, the weighted metric 235-b may be associated with a sub-channel 240-b, and the weighted metric 235-c may be associated with a sub-channel 240-c. In accordance with such associations between the set of weighted metrics 235 and the set of sub-channels 240, the wireless communication device 205 may calculate the set of weighted metrics 335 on a sub-channel-by-sub-channel basis.

For example, a first sub-channel polarization weight of an i^{th} sub-channel may be referred to as

$${W}_{1}^{i}$$

and a second sub-channel polarization weight of the i^{th} sub-channel may be referred to as

$${W}_{2}^{i} ,$$

and the wireless communication device 205 may calculate the weighted metric 235-b (which may be referred to as a combined weighted metric) for the i^{th} sub-channel as

$$a {W}_{1}^{i} + {W}_{2}^{i}$$

(as shown in the example of FIG. 2) or as

$${W}_{1}^{i} + a {W}_{2}^{i} ,$$

a being equal to a_{N_1} in the example of FIG. 2. As such, each respective weighed metric from the set of weighted metrics 235 may be associated with (such as calculated using) a respective first sub-channel polarization weight, a respective second sub-channel polarization weight, and the scaling value 230-a.

In some implementations, the first sub-channel polarization weights may be GA-based sub-channel polarization weights and the second sub-channel polarization weights may be RM-based sub-channel polarization weights. In such implementations, the wireless communication device 205 may calculate the weighted metric 235-b for the i^{th} sub-channel as

$$a {W}_{G A}^{i} + {W}_{R M}^{i} or as {W}_{G A}^{i} + a {W}_{R M}^{i} .$$

As such, with the scaling value 230-a and a formula or algorithm, the wireless communication device 205 may generate a mapping sequence for a PAC code in accordance with a hybrid (and flexible or dynamic) construction between GA and RM sequences.

If the wireless communication device 205 calculates the set of weighted metrics 235 in accordance with

$$a {W}_{G A}^{i} + {W}_{R M}^{i} ,$$

and if a=0, the set or weighted metrics 235 may be an RM sequence. Alternatively, if a→∞ or a≈∞, the set of weighted metrics 235 may be a GA sequence. For various code lengths N, the wireless communication device 205 may search for a suitable a offline and use a lookup table (via a memory of the wireless communication device 205) online. Such a suitable a may refer to an a value that provides at least a threshold signal quality, such as at least a threshold SNR or at least a threshold BLER, or both.

The wireless communication device 205, in accordance with calculating the set of weighted metrics 235 associated with the set of sub-channels 240, may perform an ordering and encoding operation 245 to obtain the message 220 for transmission to the wireless communication device 210. For example, the wireless communication device 205 may order the set of weighted metrics 235 in a descending order such that a first (such as initial) weighted metric in the descending order is associated with a highest quality sub-channel (such as a sub-channel having a highest SNR) and a last (such as final) weighted metric in the descending order is associated with a lowest quality sub-channel (such as a sub-channel having a lowest SNR). In some aspects, the descending order may be associated with a set of indexes such that the initial weighted metric is located at a first index of the descending order and the final weighted metric is located at a last index of the descending order.

The wireless communication device 205 may encode the set of information bits 225 in accordance with the descending order of the set of weighted metrics 235 to obtain the message 220 for transmission to the wireless communication device 210. The wireless communication device 205 may convey the set of information bits 225 (by transmitting the message 220) via sub-channels including at least some of the set of sub-channels 240. In some aspects, the wireless communication device 205 may transmit the message 220 via at least a subset of the set of sub-channels 240. In some aspects, the wireless communication device 205 may allocate information (such as modulation symbols or codewords) associated with the set of information bits 225 to the set of sub-channels 240 in accordance with the descending order of the set of weighted metrics 235.

Further, although illustrated in the context of the encoding performed by the wireless communication device 205, the wireless communication device 210 may decode the message 220 in accordance with the described hybrid construction of a PAC code. For example, the wireless communication device 210 may receive the message 220 via one or more of the set of sub-channels 240 and may decode the set of information bits 225 from the message 220 in accordance with the set of weighted metrics 235, which the wireless communication device 210 may calculate and order in a same or similar manner as the wireless communication device 205. As such, the wireless communication device 205 and the wireless communication device 210 may support flexible and dynamic hybrid coding mechanisms according to which the wireless communication device 205 and the wireless communication device 210 may achieve relatively greater SNR or relatively lower BLER across various (and diverse) code lengths, which may increase a reliability of communication between the wireless communication device 205 and the wireless communication device 210.

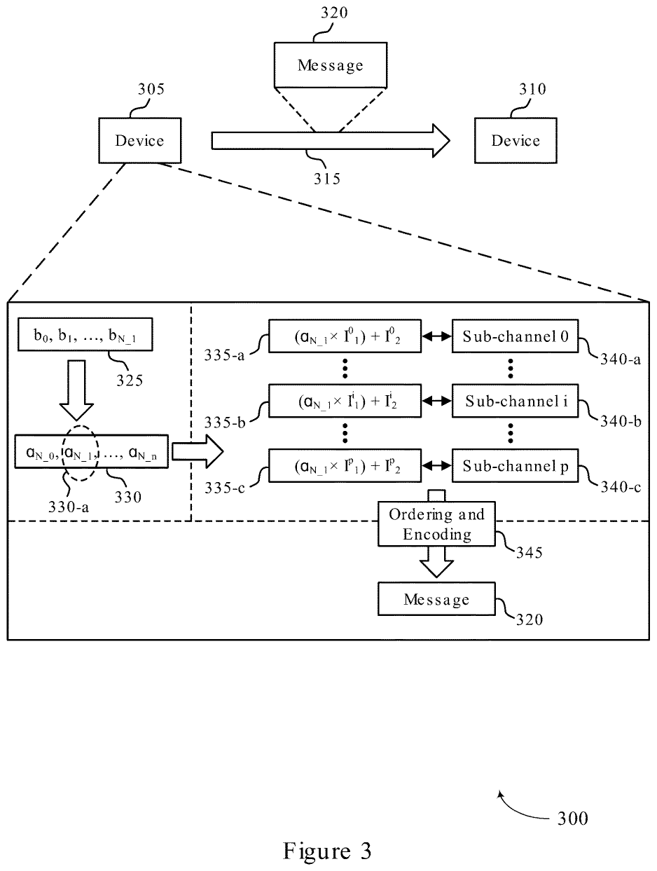

FIG. 3 shows an example encoding and signaling mechanism 300 that supports a hybrid construction of a PAC code for wireless communication. The encoding and signaling mechanism 300 may implement or be implemented to realize or facilitate aspects of the wireless communication system 100. For example, the encoding and signaling mechanism 300 illustrates wireless communication between a wireless communication device 305 and a wireless communication device 310, which may be examples of wireless communication devices as illustrated by and described with reference to FIG. 1. For example, the wireless communication device 305 and the wireless communication device 310 may be examples of a UE 115 or a network entity 105.

The wireless communication device 305 and the wireless communication device 310 may communicate with each other via a communication link 315 and, in some examples, the wireless communication device 305 may transmit a message 320 to the wireless communication device 310. In some implementations, the wireless communication device 305 and the wireless communication device 310 may communicate in accordance with a hybrid construction of a PAC code that is associated with weighted sums of indexes of two different sequences. In other words, the encoding and signaling mechanism 300 may be associated with encoding and decoding in accordance with the weighted sums of the two different sequences.

The wireless communication device 305 may select, identify, or otherwise ascertain a quantity of a set of information bits 325 that the wireless communication device 305 may transmit or otherwise convey via the message 320. As illustrated in the example of FIG. 3, the set of information bits 325 may include a quantity b_{N_1} information bits. In some implementations, the wireless communication device 305 may select a scaling value 330-a from a set of scaling values 330 in accordance with the quantity b_{N_1} information bits that are included in the set of information bits 325. As illustrated in the example of FIG. 3, the scaling value 330-a may be referred to as a scaling value a_{N_1}.

In some implementations, respective quantities of information bits by may correspond to respective scaling values a_{N} of the set of scaling values 330 in accordance with a mapping and the wireless communication device 305 may select the scaling value 330-a in accordance with the quantity b_{N_1} information bits and the mapping. Such an example mapping may be associated with a table with indexes (which may correspond to table entries) and the wireless communication device 305 may retrieve a given scaling value from the set of scaling values 330 by accessing or obtaining information from the table at a given index. In accordance with an example mapping, a scaling value a_{N_0} may correspond to a quantity b_{N_0} information bits, the scaling value a_{N_1} may correspond to the quantity b_{N_1} information bits, and a scaling value a_{N_m} may correspond to a quantity b_{N_m} information bits. In other words, the scaling value a_{N_0} may be associated with a first index of a table including the set of scaling values 330, the scaling value a_{N_1} may be associated with a second index of the table including the set of scaling values 330, and the scaling value a_{N_m} may be associated with an m^{th} index of the table including the set of scaling values 330.

In accordance with selecting the scaling value 330-a, the wireless communication device 305 may calculate (such as compute, select, identify, or otherwise determine) a set of weighted metrics 335 (including a weighted metric 335-a, a weighted metric 335-b, and a weighted metric 335-c) in accordance with first indexes of a first sequence, second indexes of a second sequence, and the scaling value 330-a. In some implementations, the wireless communication device 305 may calculate the set of weighted metrics 335 in accordance with scaling the first indexes of the first sequence or the second indexes of the second sequence by the scaling value 330-a and calculating weighted sums of the first sequence and the second sequence in accordance the scaling.

In examples in which the wireless communication device 305 scales the first indexes of the first sequence by the scaling value 330-a, the wireless communication device 305 may calculate a weighted sum in accordance with a sum of a scaled (such as weighted) first index of the first sequence and a (non-scaled or non-weighted) second index of the second sequence. Alternatively, in examples in which the wireless communication device 305 scales the second indexes of the second sequence by the scaling value 330-a, the wireless communication device 305 may calculate a weighted sum in accordance with a sum of a (non-scaled or non-weighted) first index of the first sequence and a scaled (such as weighted) second index of the second sequence. Additionally, or alternatively, the wireless communication device 305 may apply a first scaling value to the first indexes of the first sequence and a second scaling value to the second indexes of the second sequence and calculate a weighted sum in accordance with a scaled first index of the first sequence and a scaled second index of the second sequence.

The set of weighted metrics 335 may include a quantity p weighted metrics and each respective weighted metric of the set of weighted metrics 335 may be associated with (such as correspond to) a respective sub-channel of a set of sub-channels 340. For example, the weighted metric 335-a may be associated with a sub-channel 340-a, the weighted metric 335-b may be associated with a sub-channel 340-b, and the weighted metric 335-c may be associated with a sub-channel 340-c. In accordance with such associations between the set of weighted metrics 335 and the set of sub-channels 340, the wireless communication device 305 may calculate the set of weighted metrics 335 on a sub-channel-by-sub-channel basis.

For example, a first index of the first sequence of an i^{th} sub-channel may be referred to as

$${I}_{1}^{i} ,$$

a second index of the second sequence of the i^{th} sub-channel may be referred to as

$${I}_{2}^{i} ,$$

and the wireless communication device 305 may calculate the weighted metric 335-b (which may be referred to as a combined weighted metric) for the i^{th} sub-channel as

$${aI}_{1}^{i} + {I}_{2}^{i}$$

(as shown in the example of FIG. 3) or as

$${W}_{1}^{i} + a {W}_{2}^{i} ,$$

a being equal to a_{N_1}. As such, each respective weighed metric from the set of weighted metrics 335 may be associated with (such as calculated using) a respective first index of the first sequence, a respective second index of the second sequence, and the scaling value 330-a.

In some implementations, the first sequence may be a GA-based sequence and the second sequence may be RM-based sequence. In such implementations, the wireless communication device 305 may calculate the weighted metric 335-b for the i^{th} sub-channel as

$${aI}_{G A}^{i} + {I}_{R M}^{i} or as {I}_{G A}^{i} + {aI}_{R M}^{i} .$$

In some aspects, the wireless communication device 305 may sort the GA-based sequence associated with indexes

$${I}_{G A}^{i}$$

with indexes

$${I}_{R M}^{i}$$

by weight with ascending order. As such, with the scaling value 330-a and a formula or algorithm, the wireless communication device 305 may generate a mapping sequence for a PAC code in accordance with a hybrid (and flexible or dynamic) construction between GA and RM sequences.

If the wireless communication device 305 calculates the set of weighted metrics 335 in accordance with

$${aI}_{G A}^{i} + {I}_{R M}^{i} ,$$

and it a=0, the set of weighted metrics 335 may be an RM sequence. Alternatively, if a→∞ or a≈∞, the set of weighted metrics 335 may be a GA sequence. For various code lengths N, the wireless communication device 305 may search for a suitable a offline and use a lookup table (via a memory of the wireless communication device 305) online. Such a suitable a may refer to an a value that provides at least a threshold signal quality, such as at least a threshold SNR or at least a threshold BLER, or both.

The wireless communication device 305, in accordance with calculating the set of weighted metrics 335 associated with the set of sub-channels 340, may perform an ordering and encoding operation 345 to obtain the message 320 for transmission to the wireless communication device 310. For example, the wireless communication device 305 may order the set of weighted metrics 335 in an ascending order such that a first (such as initial) weighted metric in the ascending order is associated with a highest quality sub-channel (such as a sub-channel having a highest SNR) and a last (such as final) weighted metric in the ascending order is associated with a lowest quality sub-channel (such as a sub-channel having a lowest SNR). In some aspects, the ascending order may be associated with a set of indexes such that the initial weighted metric is located at a first index of the ascending order and the final weighted metric is located at a last index of the ascending order.

The wireless communication device 305 may encode the set of information bits 325 in accordance with the ascending order of the set of weighted metrics 335 to obtain the message 320 for transmission to the wireless communication device 310. The wireless communication device 305 may convey the set of information bits 325 (by transmitting the message 320) via sub-channels including at least some of the set of sub-channels 340. In some aspects, the wireless communication device 305 may transmit the message 320 via at least a subset of the set of sub-channels 340. In some aspects, the wireless communication device 305 may allocate information (such as modulation symbols or codewords) associated with the set of information bits 325 to the set of sub-channels 340 in accordance with the ascending order of the set of weighted metrics 335.

Further, although illustrated in the context of the encoding performed by the wireless communication device 305, the wireless communication device 310 may decode the message 320 in accordance with the described hybrid construction of a PAC code. For example, the wireless communication device 310 may receive the message 320 via one or more of the set of sub-channels 340 and may decode the set of information bits 325 from the message 320 in accordance with the set of weighted metrics 335, which the wireless communication device 310 may calculate and order in a same or similar manner as the wireless communication device 305. As such, the wireless communication device 305 and the wireless communication device 310 may support flexible and dynamic hybrid coding mechanisms according to which the wireless communication device 305 and the wireless communication device 310 may achieve relatively greater SNR or relatively lower BLER across various (and diverse) code lengths, which may increase a reliability of communication between the wireless communication device 305 and the wireless communication device 310.

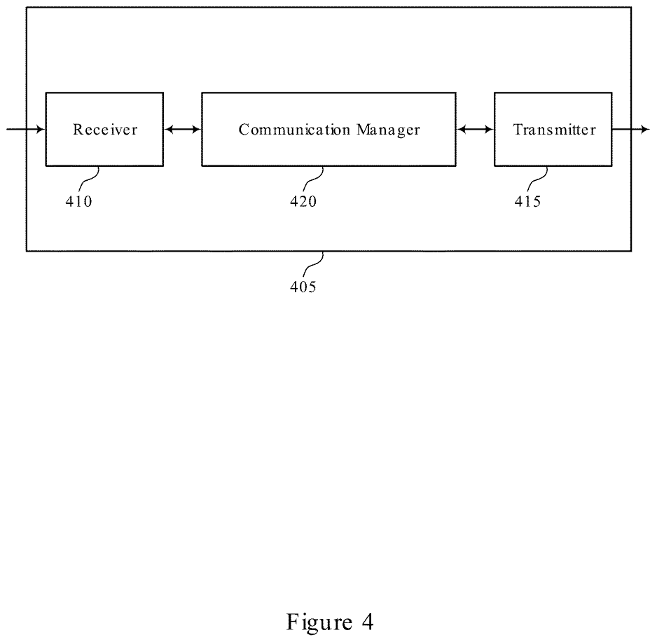

FIG. 4 shows a block diagram of a device 405 that supports a hybrid construction of a PAC code for wireless communication. The device 405 may be an example of aspects of a UE 115 or a network entity 105. The device 405 may include a receiver 410, a transmitter 415, and a communication manager 420. The communication manager 420 can be implemented, at least in part, by one or both of a modem and a processor. Each of these components may be in communication with one another (such as via one or more buses).

The receiver 410 may provide a means for receiving information such as packets, user data, control information, or any combination thereof associated with various information channels (such as control channels, data channels, information channels related to a hybrid construction of a PAC code for wireless communication). Information may be passed on to other components of the device 405. The receiver 410 may utilize a single antenna or a set of multiple antennas.

The transmitter 415 may provide a means for transmitting signals generated by other components of the device 405. For example, the transmitter 415 may transmit information such as packets, user data, control information, or any combination thereof associated with various information channels (such as control channels, data channels, information channels related to a hybrid construction of a PAC code for wireless communication). In some implementations, the transmitter 415 may be co-located with a receiver 410 in a transceiver module. The transmitter 415 may utilize a single antenna or a set of multiple antennas.

The communication manager 420, the receiver 410, the transmitter 415, or various combinations thereof or various components thereof may be examples of means for performing various aspects of a hybrid construction of a PAC code for wireless communication. For example, the communication manager 420, the receiver 410, the transmitter 415, or various combinations or components thereof may support a method for performing one or more of the functions described herein.

In some implementations, the communication manager 420, the receiver 410, the transmitter 415, or various combinations or components thereof may be implemented in hardware (such as in communication management circuitry). The hardware may include a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some implementations, a processor and memory coupled with the processor may be configured to perform one or more of the functions described herein (such as by executing, by the processor, instructions stored in the memory).

In some implementations, the communication manager 420 may be configured to perform various operations (such as receiving, obtaining, monitoring, outputting, transmitting) using or otherwise in cooperation with the receiver 410, the transmitter 415, or both. For example, the communication manager 420 may receive information from the receiver 410, send information to the transmitter 415, or be integrated in combination with the receiver 410, the transmitter 415, or both to obtain information, output information, or perform various other operations.

The communication manager 420 may support wireless communication at a wireless communication device in accordance with examples as disclosed herein. For example, the communication manager 420 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The communication manager 420 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 420 may support wireless communication at a wireless communication device in accordance with examples as disclosed herein. For example, the communication manager 420 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. The communication manager 420 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 420 may support wireless communication at a wireless communication device in accordance with examples as disclosed herein. For example, the communication manager 420 may be configured as or otherwise support a means for receiving, via a set of sub-channels, a message. The communication manager 420 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Additionally, or alternatively, the communication manager 420 may support wireless communication at a wireless communication device in accordance with examples as disclosed herein. For example, the communication manager 420 may be configured as or otherwise support a means for receiving, via a set of sub-channels, a message. The communication manager 420 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

By including or configuring the communication manager 420 in accordance with the described example implementations, the device 405 (such as a processor controlling or otherwise coupled with the receiver 410, the transmitter 415, the communication manager 420, or a combination thereof) may support techniques for reduced processing, reduced power consumption, and more efficient utilization of communication resources.

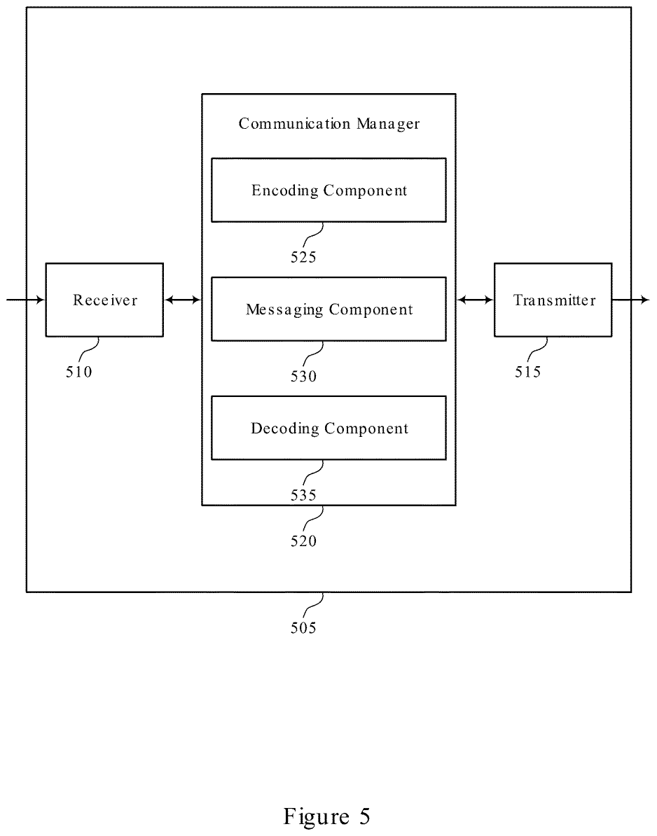

FIG. 5 shows a block diagram of a device 505 that supports a hybrid construction of a PAC code for wireless communication. The device 505 may be an example of aspects of a device 405, a UE 115, or a network entity 105. The device 505 may include a receiver 510, a transmitter 515, and a communication manager 520. The communication manager 520 can be implemented, at least in part, by one or both of a modem and a processor. Each of these components may be in communication with one another (such as via one or more buses).

The receiver 510 may provide a means for receiving information such as packets, user data, control information, or any combination thereof associated with various information channels (such as control channels, data channels, information channels related to a hybrid construction of a PAC code for wireless communication). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (such as control channels, data channels, information channels related to a hybrid construction of a PAC code for wireless communication). In some implementations, the transmitter 515 may be co-located with a receiver 510 in a transceiver module. The transmitter 515 may utilize a single antenna or a set of multiple antennas.

The device 505, or various components thereof, may be an example of means for performing various aspects of a hybrid construction of a PAC code for wireless communication. For example, the communication manager 520 may include an encoding component 525, a messaging component 530, a decoding component 535, or any combination thereof. The communication manager 520 may be an example of aspects of a communication manager 420. In some implementations, the communication manager 520, or various components thereof, may be configured to perform various operations (such as receiving, obtaining, monitoring, outputting, transmitting) using or otherwise in cooperation with the receiver 510, the transmitter 515, or both. For example, the communication manager 520 may receive information from the receiver 510, send information to the transmitter 515, or be integrated in combination with the receiver 510, the transmitter 515, or both to obtain information, output information, or perform various other operations.

The communication manager 520 may support wireless communication at a wireless communication device in accordance with examples as disclosed herein. The encoding component 525 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The messaging component 530 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 520 may support wireless communication at a wireless communication device in accordance with examples as disclosed herein. The encoding component 525 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. The messaging component 530 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 520 may support wireless communication at a wireless communication device in accordance with examples as disclosed herein. The messaging component 530 may be configured as or otherwise support a means for receiving, via a set of sub-channels, a message. The decoding component 535 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Additionally, or alternatively, the communication manager 520 may support wireless communication at a wireless communication device in accordance with examples as disclosed herein. The messaging component 530 may be configured as or otherwise support a means for receiving, via a set of sub-channels, a message. The decoding component 535 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

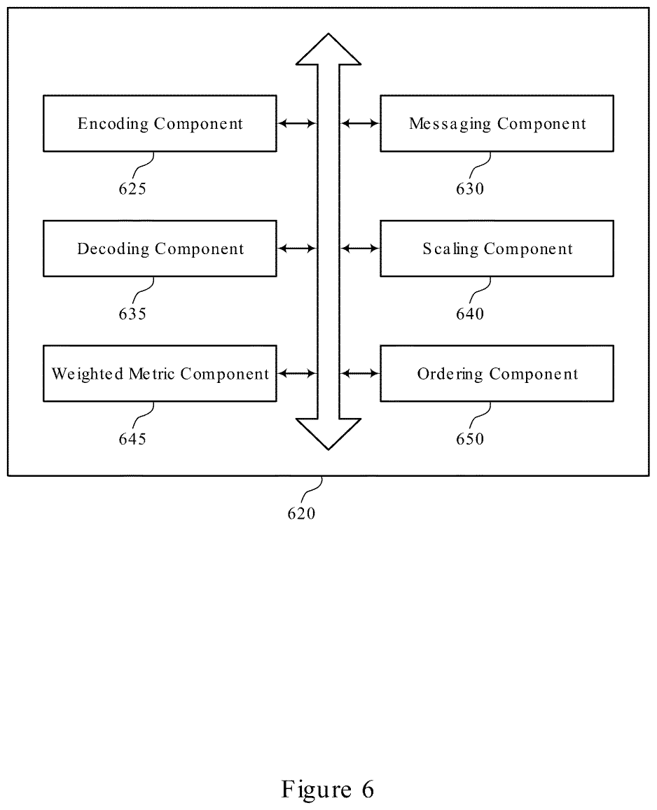

FIG. 6 shows a block diagram of a communication manager 620 that supports a hybrid construction of a PAC code for wireless communication. The communication manager 620 may be an example of aspects of a communication manager 420, a communication manager 520, or both. The communication manager 620, or various components thereof, may be an example of means for performing various aspects of a hybrid construction of a PAC code for wireless communication. For example, the communication manager 620 may include an encoding component 625, a messaging component 630, a decoding component 635, a scaling component 640, a weighted metric component 645, an ordering component 650, or any combination thereof. Each of these components may communicate, directly or indirectly, with one another (such as via one or more buses) which may include communication within a protocol layer of a protocol stack, communication associated with a logical channel of a protocol stack (such as between protocol layers of a protocol stack, within a device, component, or virtualized component associated with a network entity 105, between devices, components, or virtualized components associated with a network entity 105), or any combination thereof.

The communication manager 620 may support wireless communication at a wireless communication device in accordance with examples as disclosed herein. The encoding component 625 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The messaging component 630 may be configured as or otherwise support a means for transmitting, via a set of sub-channels including at least some of the set of multiple sub-channels, a message in accordance with encoding the set of information bits in accordance with the set of multiple weighted metrics.

In some implementations, the scaling component 640 may be configured as or otherwise support a means for selecting the scaling value associated with the first weighted metric from a set of multiple scaling values in accordance with a quantity of the set of information bits.

In some implementations, respective quantities of information bits correspond to respective scaling values of the set of multiple scaling values.

In some implementations, the scaling component 640 may be configured as or otherwise support a means for scaling the first sub-channel polarization weight or the second sub-channel polarization weight in accordance with the scaling value. In some implementations, the weighted metric component 645 may be configured as or otherwise support a means for selecting, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.

In some implementations, the ordering component 650 may be configured as or otherwise support a means for ordering the set of multiple weighted metrics in a descending order, an initial weighted metric in the descending order of the set of multiple weighted metrics being associated with a highest quality sub-channel and a final weighted metric in the descending order of the set of multiple weighted metrics being associated with a lowest quality sub-channel. In some examples, encoding the set of information bits is associated with the descending order of the set of multiple weighted metrics.

In some implementations, each respective weighted metric from the set of multiple weighted metrics is associated with a respective first sub-channel polarization weight, a respective second sub-channel polarization weight, and the scaling value.

In some implementations, the first sub-channel polarization weight corresponds to a Gaussian approximation-based sub-channel polarization weight for a sub-channel associated with the first weighted metric and the second sub-channel polarization weight corresponds to a Reed-Muller-based sub-channel polarization weight for the sub-channel associated with the first weighted metric. In some implementations, the first weighted metric is equal to a weighted sum of the Gaussian approximation-based sub-channel polarization weight and the Reed-Muller-based sub-channel polarization weight in accordance with the scaling value.

In some implementations, the set of multiple weighted metrics are associated with a hybrid construction of a PAC code. In some implementations, each respective weighted metric of the set of multiple weighted metrics is associated with a respective Gaussian approximation-based sub-channel polarization weight, a respective Reed-Muller-based sub-channel polarization weight, and the scaling value in accordance with the hybrid construction.

Additionally, or alternatively, the communication manager 620 may support wireless communication at a wireless communication device in accordance with examples as disclosed herein. In some implementations, the encoding component 625 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. In some implementations, the messaging component 630 may be configured as or otherwise support a means for transmitting, via a set of sub-channels including at least some of the set of multiple sub-channels, a message in accordance with encoding the set of information bits in accordance with the set of multiple weighted metrics.

In some implementations, the scaling component 640 may be configured as or otherwise support a means for selecting the scaling value associated with the first weighted metric from a set of multiple scaling values in accordance with a quantity of the set of information bits.

In some implementations, respective quantities of information bits correspond to respective scaling values of the set of multiple scaling values.

In some implementations, the scaling component 640 may be configured as or otherwise support a means for scaling the first index of the first sequence or the second index of the second sequence in accordance with the scaling value. In some implementations, the weighted metric component 645 may be configured as or otherwise support a means for selecting, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.

In some implementations, the ordering component 650 may be configured as or otherwise support a means for ordering the set of multiple weighted metrics in an ascending order, an initial weighted metric in the ascending order of the set of multiple weighted metrics being associated with a highest quality sub-channel and a final weighted metric in the ascending order of the set of multiple weighted metrics being associated with a lowest quality sub-channel. In some examples, encoding the set of information bits is associated with the ascending order of the set of multiple weighted metrics.

In some implementations, each respective weighted metric from the set of multiple weighted metrics is associated with a respective first index of the first sequence, a respective second index of the second sequence, and the scaling value.

In some implementations, the first index of the first sequence corresponds to a Gaussian approximation-based sequence index for a sub-channel associated with the first weighted metric and the second index of the second sequence corresponds to a Reed-Muller-based sequence index for the sub-channel associated with the first weighted metric. In some implementations, the first weighted metric is equal to a weighted sum of the Gaussian approximation-based sequence index and the Reed-Muller-based sequence index in accordance with the scaling value.

In some implementations, the set of multiple weighted metrics are associated with a hybrid construction of a PAC code. In some implementations, each respective weighted metric of the set of multiple weighted metrics is associated with a respective Gaussian approximation-based sequence index, a respective Reed-Muller-based sequence index, and the scaling value in accordance with the hybrid construction.

Additionally, or alternatively, the communication manager 620 may support wireless communication at a wireless communication device in accordance with examples as disclosed herein. In some implementations, the messaging component 630 may be configured as or otherwise support a means for receiving, via a set of sub-channels, a message. The decoding component 635 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

In some implementations, the scaling component 640 may be configured as or otherwise support a means for selecting the scaling value associated with the first weighted metric from a set of multiple scaling values in accordance with a quantity of the set of information bits.

In some implementations, respective quantities of information bits correspond to respective scaling values of the set of multiple scaling values.

In some implementations, the scaling component 640 may be configured as or otherwise support a means for scaling the first sub-channel polarization weight or the second sub-channel polarization weight in accordance with the scaling value. In some implementations, the weighted metric component 645 may be configured as or otherwise support a means for selecting, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.

In some implementations, the ordering component 650 may be configured as or otherwise support a means for ordering the set of multiple weighted metrics in a descending order, an initial weighted metric in the descending order of the set of multiple weighted metrics being associated with a highest quality sub-channel and a final weighted metric in the descending order of the set of multiple weighted metrics being associated with a lowest quality sub-channel. In some examples, decoding the set of information bits is associated with the descending order of the set of multiple weighted metrics.

In some implementations, each respective weighted metric from the set of multiple weighted metrics is associated with a respective first sub-channel polarization weight, a respective second sub-channel polarization weight, and the scaling value.

In some implementations, the first sub-channel polarization weight corresponds to a Gaussian approximation-based sub-channel polarization weight for a sub-channel associated with the first weighted metric and the second sub-channel polarization weight corresponds to a Reed-Muller-based sub-channel polarization weight for the sub-channel associated with the first weighted metric. In some implementations, the first weighted metric is equal to a weighted sum of the Gaussian approximation-based sub-channel polarization weight and the Reed-Muller-based sub-channel polarization weight in accordance with the scaling value.

In some implementations, the set of multiple weighted metrics are associated with a hybrid construction of a PAC code. In some implementations, each respective weighted metric of the set of multiple weighted metrics is associated with a respective Gaussian approximation-based sub-channel polarization weight, a respective Reed-Muller-based sub-channel polarization weight, and the scaling value in accordance with the hybrid construction.

Additionally, or alternatively, the communication manager 620 may support wireless communication at a wireless communication device in accordance with examples as disclosed herein. In some implementations, the messaging component 630 may be configured as or otherwise support a means for receiving, via a set of sub-channels, a message. In some implementations, the decoding component 635 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

In some implementations, the scaling component 640 may be configured as or otherwise support a means for selecting the scaling value associated with the first weighted metric from a set of multiple scaling values in accordance with a quantity of the set of information bits.

In some implementations, respective quantities of information bits correspond to respective scaling values of the set of multiple scaling values.

In some implementations, the scaling component 640 may be configured as or otherwise support a means for scaling the first index of the first sequence or the second index of the second sequence in accordance with the scaling value. In some implementations, the weighted metric component 645 may be configured as or otherwise support a means for selecting, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.

In some implementations, the ordering component 650 may be configured as or otherwise support a means for ordering the set of multiple weighted metrics in an ascending order, an initial weighted metric in the ascending order of the set of multiple weighted metrics being associated with a highest quality sub-channel and a final weighted metric in the ascending order of the set of multiple weighted metrics being associated with a lowest quality sub-channel. In some examples, decoding the set of information bits is associated with the ascending order of the set of multiple weighted metrics.

In some implementations, each respective weighted metric from the set of multiple weighted metrics is associated with a respective first index of the first sequence, a respective second index of the second sequence, and the scaling value.

In some implementations, the first index of the first sequence corresponds to a Gaussian approximation-based sequence index for a sub-channel associated with the first weighted metric and the second index of the second sequence corresponds to a Reed-Muller-based sequence index for the sub-channel associated with the first weighted metric. In some implementations, the first weighted metric is equal to a weighted sum of the Gaussian approximation-based sequence index and the Reed-Muller-based sequence index in accordance with the scaling value.

In some implementations, the set of multiple weighted metrics are associated with a hybrid construction of a PAC code. In some implementations, each respective weighted metric of the set of multiple weighted metrics is associated with a respective Gaussian approximation-based sequence index, a respective Reed-Muller-based sequence index, and the scaling value in accordance with the hybrid construction.

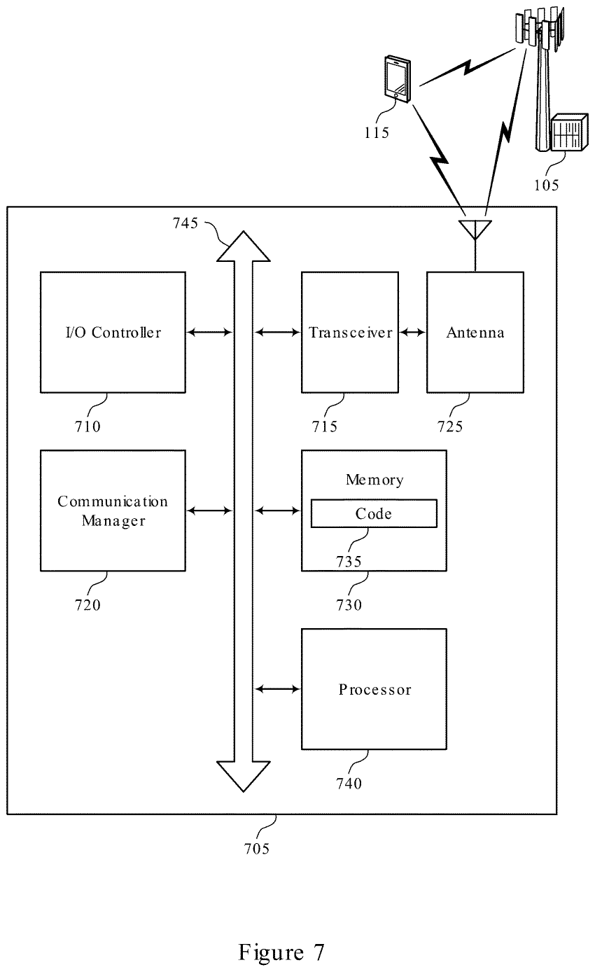

FIG. 7 shows a diagram of a system including a device 705 that supports a hybrid construction of a PAC code for wireless communication. The device 705 may be an example of or include the components of a device 405, a device 505, or a UE 115. The device 705 may communicate (such as wirelessly) with one or more network entities 105, one or more UEs 115, or any combination thereof. The device 705 may include components for bi-directional voice and data communication including components for transmitting and receiving communication, such as a communication manager 720, an input/output (I/O) controller 710, a transceiver 715, an antenna 725, a memory 730, code 735, and a processor 740. These components may be in electronic communication or otherwise coupled (such as operatively, communicatively, functionally, electronically, electrically) via one or more buses (such as a bus 745).

The I/O controller 710 may manage input and output signals for the device 705. The I/O controller 710 also may manage peripherals not integrated into the device 705. In some examples, the I/O controller 710 may represent a physical connection or port to an external peripheral. In some examples, the I/O controller 710 may utilize an operating system such as iOS®, ANDROID®, MS-DOS®, MS-WINDOWS®, OS/2®, UNIX®, LINUX®, or another known operating system. Additionally, or alternatively, the I/O controller 710 may represent or interact with a modem, a keyboard, a mouse, a touchscreen, or a similar device. In some examples, the I/O controller 710 may be implemented as part of a processor, such as the processor 740. In some examples, a user may interact with the device 705 via the I/O controller 710 or via hardware components controlled by the I/O controller 710.

In some examples, the device 705 may include a single antenna 725. However, in some other examples, the device 705 may have more than one antenna 725, which may be capable of concurrently transmitting or receiving multiple wireless transmissions. The transceiver 715 may communicate bi-directionally, via the one or more antennas 725, wired, or wireless links. For example, the transceiver 715 may represent a wireless transceiver and may communicate bi-directionally with another wireless transceiver. The transceiver 715 also may include a modem to modulate the packets, to provide the modulated packets to one or more antennas 725 for transmission, and to demodulate packets received from the one or more antennas 725. The transceiver 715, or the transceiver 715 and one or more antennas 725, may be an example of a transmitter 415, a transmitter 515, a receiver 410, a receiver 510, or any combination thereof or component thereof.

The memory 730 may include random access memory (RAM) and read-only memory (ROM). The memory 730 may store computer-readable, computer-executable code 735 including instructions that, when executed by the processor 740, cause the device 705 to perform various functions described herein. The code 735 may be stored in a non-transitory computer-readable medium such as system memory or another type of memory. In some examples, the code 735 may not be directly executable by the processor 740 but may cause a computer (such as when compiled and executed) to perform functions described herein. In some examples, the memory 730 may contain, among other things, a basic I/O system (BIOS) which may control basic hardware or software operation such as the interaction with peripheral components or devices.

The processor 740 may include an intelligent hardware device (such as a general-purpose processor, a DSP, a CPU, a microcontroller, an ASIC, an FPGA, a programmable logic device, a discrete gate or transistor logic component, a discrete hardware component, or any combination thereof). In some examples, the processor 740 may be configured to operate a memory array using a memory controller. In some other examples, a memory controller may be integrated into the processor 740. The processor 740 may be configured to execute computer-readable instructions stored in a memory (such as the memory 730) to cause the device 705 to perform various functions (such as functions or tasks supporting a hybrid construction of a PAC code for wireless communication). For example, the device 705 or a component of the device 705 may include a processor 740 and memory 730 coupled with or to the processor 740, the processor 740 and memory 730 configured to perform various functions described herein.

The communication manager 720 may support wireless communication at a wireless communication device in accordance with examples as disclosed herein. For example, the communication manager 720 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The communication manager 720 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 720 may support wireless communication at a wireless communication device in accordance with examples as disclosed herein. For example, the communication manager 720 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. The communication manager 720 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 720 may support wireless communication at a wireless communication device in accordance with examples as disclosed herein. For example, the communication manager 720 may be configured as or otherwise support a means for receiving, via a set of sub-channels, a message. The communication manager 720 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Additionally, or alternatively, the communication manager 720 may support wireless communication at a wireless communication device in accordance with examples as disclosed herein. For example, the communication manager 720 may be configured as or otherwise support a means for receiving, via a set of sub-channels, a message. The communication manager 720 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

By including or configuring the communication manager 720 in accordance with the described example implementations, the device 705 may support techniques for greater communication reliability, reduced latency, greater user experience related to reduced processing, reduced power consumption, more efficient utilization of communication resources, greater coordination between devices, longer battery life, and greater utilization of processing capability.

In some implementations, the communication manager 720 may be configured to perform various operations (such as receiving, monitoring, transmitting) using or otherwise in cooperation with the transceiver 715, the one or more antennas 725, or any combination thereof. Although the communication manager 720 is illustrated as a separate component, in some examples, one or more functions described with reference to the communication manager 720 may be supported by or performed by the processor 740, the memory 730, the code 735, or any combination thereof. For example, the code 735 may include instructions executable by the processor 740 to cause the device 705 to perform various aspects of a hybrid construction of a PAC code for wireless communication, or the processor 740 and the memory 730 may be otherwise configured to perform or support such operations.

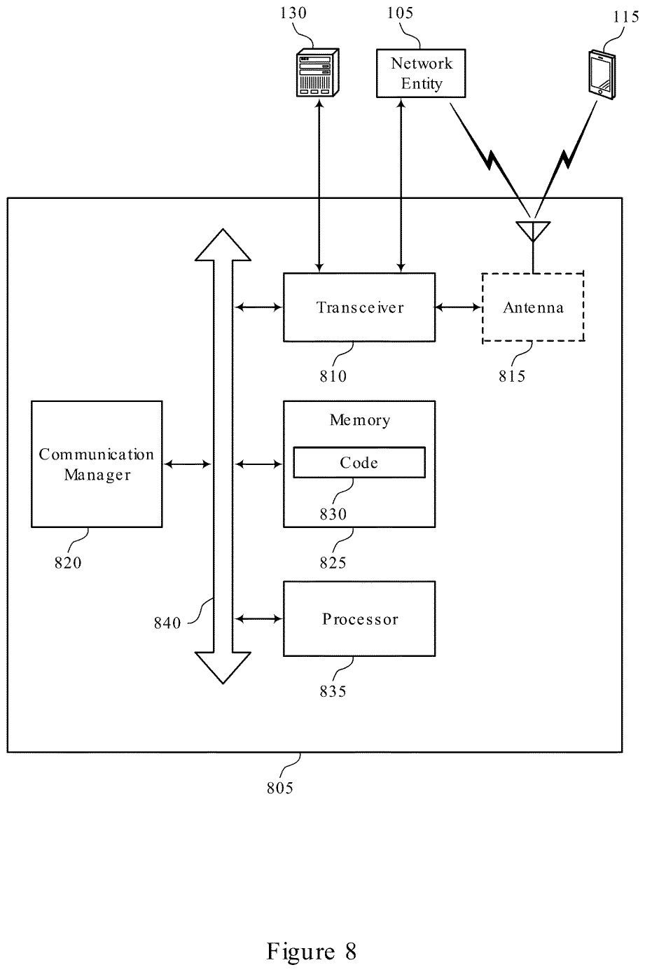

FIG. 8 shows a diagram of a system including a device 805 that supports a hybrid construction of a PAC code for wireless communication. The device 805 may be an example of or include the components of a device 405, a device 505, or a network entity 105. The device 805 may communicate with one or more network entities 105, one or more UEs 115, or any combination thereof, which may include communication over one or more wired interfaces, over one or more wireless interfaces, or any combination thereof. The device 805 may include components that support outputting and obtaining communication, such as a communication manager 820, a transceiver 810, an antenna 815, a memory 825, code 830, and a processor 835. These components may be in electronic communication or otherwise coupled (such as operatively, communicatively, functionally, electronically, electrically) via one or more buses (such as a bus 840).

The transceiver 810 may support bi-directional communication via wired links, wireless links, or both. In some implementations, the transceiver 810 may include a wired transceiver and may communicate bi-directionally with another wired transceiver. Additionally, or alternatively, in some examples, the transceiver 810 may include a wireless transceiver and may communicate bi-directionally with another wireless transceiver. In some implementations, the device 805 may include one or more antennas 815, which may be capable of transmitting or receiving wireless transmissions (such as concurrently). The transceiver 810 also may include a modem to modulate signals, to provide the modulated signals for transmission (such as by one or more antennas 815, by a wired transmitter), to receive modulated signals (such as from one or more antennas 815, from a wired receiver), and to demodulate signals.

In some implementations, the transceiver 810 may include one or more interfaces, such as one or more interfaces coupled with the one or more antennas 815 that are configured to support various receiving or obtaining operations, or one or more interfaces coupled with the one or more antennas 815 that are configured to support various transmitting or outputting operations, or a combination thereof. In some implementations, the transceiver 810 may include or be configured for coupling with one or more processors or memory components that are operable to perform or support operations based on received or obtained information or signals, or to generate information or other signals for transmission or other outputting, or any combination thereof. In some implementations, the transceiver 810, or the transceiver 810 and the one or more antennas 815, or the transceiver 810 and the one or more antennas 815 and one or more processors or memory components (such as the processor 835, or the memory 825, or both), may be included in a chip or chip assembly that is installed in the device 805. In some implementations, the transceiver may be operable to support communication via one or more communication links (such as a communication link 125, a backhaul communication link 120, a midhaul communication link 162, a fronthaul communication link 168).

The memory 825 may include RAM and ROM. The memory 825 may store computer-readable, computer-executable code 830 including instructions that, when executed by the processor 835, cause the device 805 to perform various functions described herein. The code 830 may be stored in a non-transitory computer-readable medium such as system memory or another type of memory. In some examples, the code 830 may not be directly executable by the processor 835 but may cause a computer (such as when compiled and executed) to perform functions described herein. In some examples, the memory 825 may contain, among other things, a BIOS which may control basic hardware or software operation such as the interaction with peripheral components or devices.

The processor 835 may include an intelligent hardware device (such as a general-purpose processor, a DSP, an ASIC, a CPU, an FPGA, a microcontroller, a programmable logic device, discrete gate or transistor logic, a discrete hardware component, or any combination thereof). In some examples, the processor 835 may be configured to operate a memory array using a memory controller. In some other cases, a memory controller may be integrated into the processor 835. The processor 835 may be configured to execute computer-readable instructions stored in a memory (such as the memory 825) to cause the device 805 to perform various functions (such as functions or tasks supporting a hybrid construction of a PAC code for wireless communication). For example, the device 805 or a component of the device 805 may include a processor 835 and memory 825 coupled with the processor 835, the processor 835 and memory 825 configured to perform various functions described herein. The processor 835 may be an example of a cloud-computing platform (such as one or more physical nodes and supporting software such as operating systems, virtual machines, or container instances) that may host the functions (such as by executing code 830) to perform the functions of the device 805. The processor 835 may be any one or more suitable processors capable of executing scripts or instructions of one or more software programs stored in the device 805 (such as within the memory 825).

In some implementations, the processor 835 may be a component of a processing system. A processing system may generally refer to a system or series of machines or components that receives inputs and processes the inputs to produce a set of outputs (which may be passed to other systems or components of, for example, the device 805). For example, a processing system of the device 805 may refer to a system including the various other components or subcomponents of the device 805, such as the processor 835, or the transceiver 810, or the communication manager 820, or other components or combinations of components of the device 805. The processing system of the device 805 may interface with other components of the device 805, and may process information received from other components (such as inputs or signals) or output information to other components. For example, a chip or modem of the device 805 may include a processing system and one or more interfaces to output information, or to obtain information, or both.

The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 805 may transmit information output from the chip or modem. Additionally, or alternatively, in some implementations, the one or more interfaces may refer to an interface between the processing system of the chip or modem and a receiver, such that the device 805 may obtain information or signal inputs, and the information may be passed to the processing system. A person having ordinary skill in the art will readily recognize that a first interface also may obtain information or signal inputs, and a second interface also may output information or signal outputs.

In some implementations, a bus 840 may support communication of (such as within) a protocol layer of a protocol stack. In some implementations, a bus 840 may support communication associated with a logical channel of a protocol stack (such as between protocol layers of a protocol stack), which may include communication performed within a component of the device 805, or between different components of the device 805 that may be co-located or located in different locations (such that the device 805 may refer to a system in which one or more of the communication manager 820, the transceiver 810, the memory 825, the code 830, and the processor 835 may be located in one of the different components or divided between different components).

In some implementations, the communication manager 820 may manage aspects of communication with a core network 130 (such as via one or more wired or wireless backhaul links). For example, the communication manager 820 may manage the transfer of data communication for client devices, such as one or more UEs 115. In some implementations, the communication manager 820 may manage communication with other network entities 105, and may include a controller or scheduler for controlling communication with UEs 115 in cooperation with other network entities 105. In some implementations, the communication manager 820 may support an X2 interface within an LTE/LTE-A wireless communication network technology to provide communication between network entities 105.

The communication manager 820 may support wireless communication at a wireless communication device in accordance with examples as disclosed herein. For example, the communication manager 820 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The communication manager 820 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 820 may support wireless communication at a wireless communication device in accordance with examples as disclosed herein. For example, the communication manager 820 may be configured as or otherwise support a means for encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. The communication manager 820 may be configured as or otherwise support a means for transmitting, via a set of sub-channels including at least some of the set of multiple sub-channels, a message in accordance with encoding the set of information bits in accordance with the set of multiple weighted metrics.

Additionally, or alternatively, the communication manager 820 may support wireless communication at a wireless communication device in accordance with examples as disclosed herein. For example, the communication manager 820 may be configured as or otherwise support a means for receiving, via a set of sub-channels, a message. The communication manager 820 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value.

Additionally, or alternatively, the communication manager 820 may support wireless communication at a wireless communication device in accordance with examples as disclosed herein. For example, the communication manager 820 may be configured as or otherwise support a means for receiving, via a set of sub-channels, a message. The communication manager 820 may be configured as or otherwise support a means for decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value.

By including or configuring the communication manager 820 in accordance with the described example implementations, the device 805 may support techniques for greater communication reliability, reduced latency, greater user experience related to reduced processing, reduced power consumption, more efficient utilization of communication resources, greater coordination between devices, longer battery life, and greater utilization of processing capability.

In some implementations, the communication manager 820 may be configured to perform various operations (such as receiving, obtaining, monitoring, outputting, transmitting) using or otherwise in cooperation with the transceiver 810, the one or more antennas 815 (as applicable), or any combination thereof. Although the communication manager 820 is illustrated as a separate component, in some examples, one or more functions described with reference to the communication manager 820 may be supported by or performed by the transceiver 810, the processor 835, the memory 825, the code 830, or any combination thereof. For example, the code 830 may include instructions executable by the processor 835 to cause the device 805 to perform various aspects of a hybrid construction of a PAC code for wireless communication, or the processor 835 and the memory 825 may be otherwise configured to perform or support such operations.

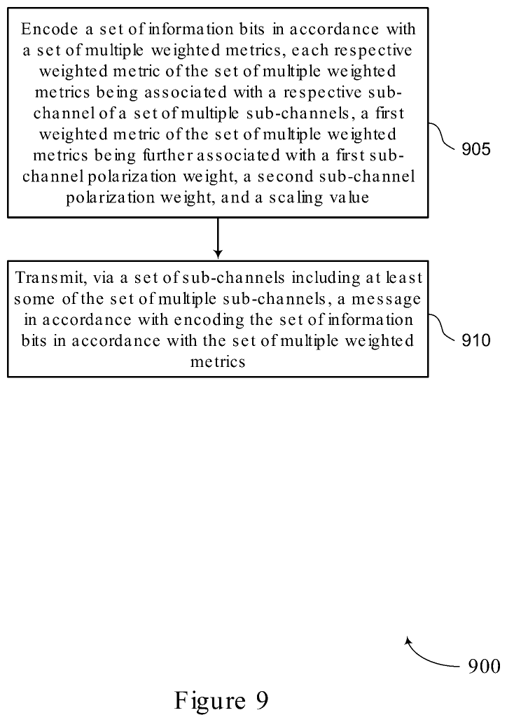

FIG. 9 shows a flowchart illustrating a method 900 that supports a hybrid construction of a PAC code for wireless communication. The operations of the method 900 may be implemented by a UE or a network entity or its components. For example, the operations of the method 900 may be performed by a UE 115 or a network entity as described with reference to FIGS. 1-8. In some implementations, a UE or a network entity may execute a set of instructions to control the functional elements of the UE or the network entity to perform the described functions. Additionally, or alternatively, the UE or the network entity may perform aspects of the described functions using special-purpose hardware.

At 905, the method may include encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first sub-channel polarization weight, a second sub-channel polarization weight, and a scaling value. The operations of 905 may be performed in accordance with examples as disclosed herein. In some implementations, aspects of the operations of 905 may be performed by an encoding component 625 as described with reference to FIG. 6.

At 910, the method may include transmitting, via a set of sub-channels including at least some of the set of multiple sub-channels, a message in accordance with encoding the set of information bits in accordance with the set of multiple weighted metrics. The operations of 910 may be performed in accordance with examples as disclosed herein. In some implementations, aspects of the operations of 910 may be performed by a messaging component 630 as described with reference to FIG. 6.

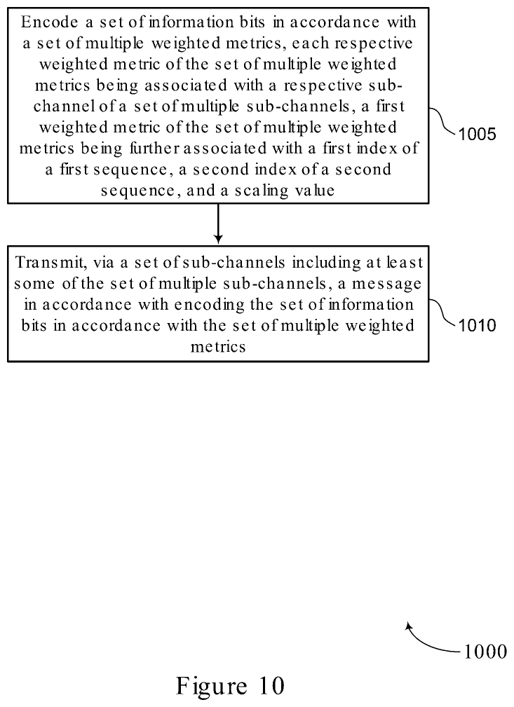

FIG. 10 shows a flowchart illustrating a method 1000 that supports a hybrid construction of a PAC code for wireless communication. The operations of the method 1000 may be implemented by a UE or a network entity or its components. For example, the operations of the method 1000 may be performed by a UE 115 or a network entity as described with reference to FIGS. 1-8. In some implementations, a UE or a network entity may execute a set of instructions to control the functional elements of the UE or the network entity to perform the described functions. Additionally, or alternatively, the UE or the network entity may perform aspects of the described functions using special-purpose hardware.

At 1005, the method may include encoding a set of information bits in accordance with a set of multiple weighted metrics, each respective weighted metric of the set of multiple weighted metrics being associated with a respective sub-channel of a set of multiple sub-channels, a first weighted metric of the set of multiple weighted metrics being further associated with a first index of a first sequence, a second index of a second sequence, and a scaling value. The operations of 1005 may be performed in accordance with examples as disclosed herein. In some implementations, aspects of the operations of 1005 may be performed by an encoding component 625 as described with reference to FIG. 6.

At 1010, the method may include transmitting, via a set of sub-channels including at least some of the set of multiple sub-channels, a message in accordance with encoding the set of information bits in accordance with the set of multiple weighted metrics. The operations of 1010 may be performed in accordance with examples as disclosed herein. In some implementations, aspects of the operations of 1010 may be performed by a messaging component 630 as described with reference to FIG. 6.

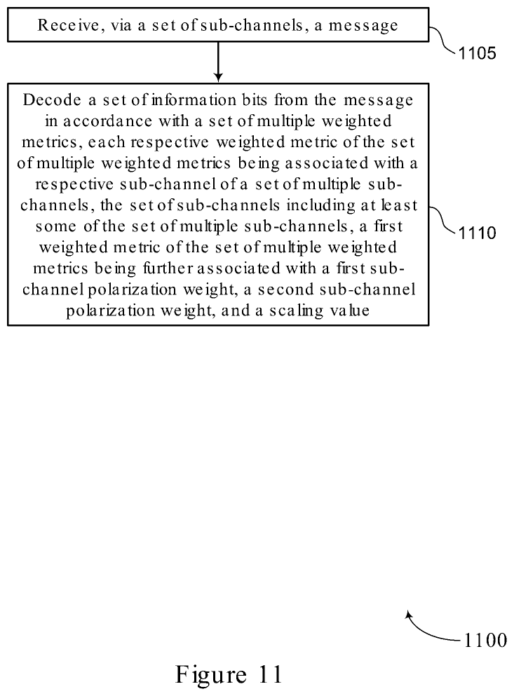

FIG. 11 shows a flowchart illustrating a method 1100 that supports a hybrid construction of a PAC code for wireless communication. The operations of the method 1100 may be implemented by a UE or a network entity or its components. For example, the operations of the method 1100 may be performed by a UE 115 or a network entity as described with reference to FIGS. 1-8. In some implementations, a UE or a network entity may execute a set of instructions to control the functional elements of the UE or the network entity to perform the described functions. Additionally, or alternatively, the UE or the network entity may perform aspects of the described functions using special-purpose hardware.

At 1105, the method may include receiving, via a set of sub-channels, a message. The operations of 1105 may be performed in accordance with examples as disclosed herein. In some implementations, aspects of the operations of 1105 may be performed by a messaging component 630 as described with reference to FIG. 6.

At 1110, the method may include decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first sub-channel polarization weight, a second sub-channel polarization weight, and a scaling value. The operations of 1110 may be performed in accordance with examples as disclosed herein. In some implementations, aspects of the operations of 1110 may be performed by a decoding component 635 as described with reference to FIG. 6.

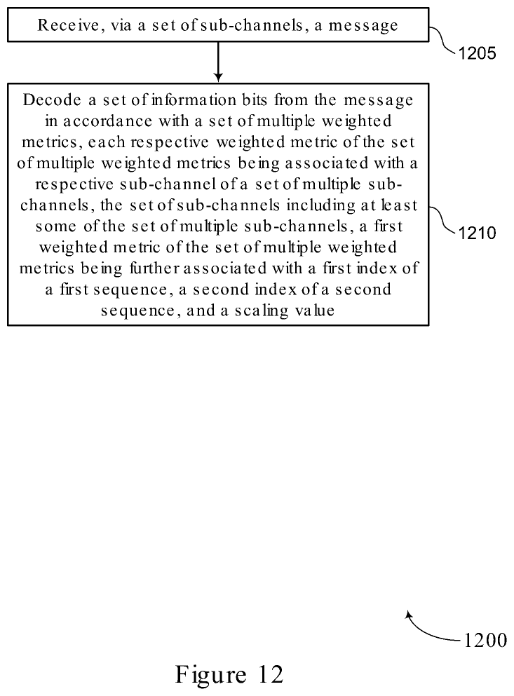

FIG. 12 shows a flowchart illustrating a method 1200 that supports a hybrid construction of a PAC code for wireless communication. The operations of the method 1200 may be implemented by a UE or a network entity or its components. For example, the operations of the method 1200 may be performed by a UE 115 or a network entity as described with reference to FIGS. 1-8. In some implementations, a UE or a network entity may execute a set of instructions to control the functional elements of the UE or the network entity to perform the described functions. Additionally, or alternatively, the UE or the network entity may perform aspects of the described functions using special-purpose hardware.

At 1205, the method may include receiving, via a set of sub-channels, a message. The operations of 1205 may be performed in accordance with examples as disclosed herein. In some implementations, aspects of the operations of 1205 may be performed by a messaging component 630 as described with reference to FIG. 6.

At 1210, the method may include decoding a set of information bits from the message in accordance with a set of multiple weighted metrics, each respective weighted metric of the set of multiple weighted metrics being associated with a respective sub-channel of a set of multiple sub-channels, the set of sub-channels including at least some of the set of multiple sub-channels, a first weighted metric of the set of multiple weighted metrics being further associated with a first index of a first sequence, a second index of a second sequence, and a scaling value. The operations of 1210 may be performed in accordance with examples as disclosed herein. In some implementations, aspects of the operations of 1210 may be performed by a decoding component 635 as described with reference to FIG. 6.

The following provides an overview of aspects of the present disclosure:
Aspect 1: A method for wireless communication at a wireless communication device, comprising: encoding a set of information bits in accordance with a plurality of weighted metrics, each respective weighted metric of the plurality of weighted metrics being associated with a respective sub-channel of a plurality of sub-channels, a first weighted metric of the plurality of weighted metrics being further associated with a first sub-channel polarization weight, a second sub-channel polarization weight, and a scaling value; and transmitting, via a set of sub-channels comprising at least some of the plurality of sub-channels, a message in accordance with encoding the set of information bits in accordance with the plurality of weighted metrics.
Aspect 2: The method of aspect 1, further comprising: selecting the scaling value associated with the first weighted metric from a plurality of scaling values in accordance with a quantity of the set of information bits.
Aspect 3: The method of aspect 2, wherein respective quantities of information bits correspond to respective scaling values of the plurality of scaling values.
Aspect 4: The method of any of aspects 1-3, further comprising: scaling the first sub-channel polarization weight or the second sub-channel polarization weight in accordance with the scaling value; and selecting, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.
Aspect 5: The method of any of aspects 1-4, further comprising: ordering the plurality of weighted metrics in a descending order, an initial weighted metric in the descending order of the plurality of weighted metrics being associated with a highest quality sub-channel and a final weighted metric in the descending order of the plurality of weighted metrics being associated with a lowest quality sub-channel, wherein encoding the set of information bits is associated with the descending order of the plurality of weighted metrics.
Aspect 6: The method of any of aspects 1-5, wherein each respective weighted metric from the plurality of weighted metrics is associated with a respective first sub-channel polarization weight, a respective second sub-channel polarization weight, and the scaling value.
Aspect 7: The method of any of aspects 1-6, wherein the first sub-channel polarization weight corresponds to a Gaussian approximation-based sub-channel polarization weight for a sub-channel associated with the first weighted metric and the second sub-channel polarization weight corresponds to a Reed-Muller-based sub-channel polarization weight for the sub-channel associated with the first weighted metric, and the first weighted metric is equal to a weighted sum of the Gaussian approximation-based sub-channel polarization weight and the Reed-Muller-based sub-channel polarization weight in accordance with the scaling value.
Aspect 8: The method of aspect 7, wherein the plurality of weighted metrics are associated with a hybrid construction of a polarization-adjusted convolutional code, and each respective weighted metric of the plurality of weighted metrics is associated with a respective Gaussian approximation-based sub-channel polarization weight, a respective Reed-Muller-based sub-channel polarization weight, and the scaling value in accordance with the hybrid construction.
Aspect 9: A method for wireless communication at a wireless communication device, comprising: encoding a set of information bits in accordance with a plurality of weighted metrics, each respective weighted metric of the plurality of weighted metrics being associated with a respective sub-channel of a plurality of sub-channels, a first weighted metric of the plurality of weighted metrics being further associated with a first index of a first sequence, a second index of a second sequence, and a scaling value; and transmitting, via a set of sub-channels comprising at least some of the plurality of sub-channels, a message in accordance with encoding the set of information bits in accordance with the plurality of weighted metrics.
Aspect 10: The method of aspect 9, further comprising: selecting the scaling value associated with the first weighted metric from a plurality of scaling values in accordance with a quantity of the set of information bits.
Aspect 11: The method of aspect 10, wherein respective quantities of information bits correspond to respective scaling values of the plurality of scaling values.
Aspect 12: The method of any of aspects 9-11, further comprising: scaling the first index of the first sequence or the second index of the second sequence in accordance with the scaling value; and selecting, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.
Aspect 13: The method of any of aspects 9-12, further comprising: ordering the plurality of weighted metrics in an ascending order, an initial weighted metric in the ascending order of the plurality of weighted metrics being associated with a highest quality sub-channel and a final weighted metric in the ascending order of the plurality of weighted metrics being associated with a lowest quality sub-channel, wherein encoding the set of information bits is associated with the ascending order of the plurality of weighted metrics.
Aspect 14: The method of any of aspects 9-13, wherein each respective weighted metric from the plurality of weighted metrics is associated with a respective first index of the first sequence, a respective second index of the second sequence, and the scaling value.
Aspect 15: The method of any of aspects 9-14, wherein the first index of the first sequence corresponds to a Gaussian approximation-based sequence index for a sub-channel associated with the first weighted metric and the second index of the second sequence corresponds to a Reed-Muller-based sequence index for the sub-channel associated with the first weighted metric, and the first weighted metric is equal to a weighted sum of the Gaussian approximation-based sequence index and the Reed-Muller-based sequence index in accordance with the scaling value.
Aspect 16: The method of aspect 15, wherein the plurality of weighted metrics are associated with a hybrid construction of a polarization-adjusted convolutional code, and each respective weighted metric of the plurality of weighted metrics is associated with a respective Gaussian approximation-based sequence index, a respective Reed-Muller-based sequence index, and the scaling value in accordance with the hybrid construction.

Aspect 17: A method for wireless communication at a wireless communication device, comprising: receiving, via a set of sub-channels, a message; and decoding a set of information bits from the message in accordance with a plurality of weighted metrics, each respective weighted metric of the plurality of weighted metrics being associated with a respective sub-channel of a plurality of sub-channels, the set of sub-channels comprising at least some of the plurality of sub-channels, a first weighted metric of the plurality of weighted metrics being further associated with a first sub-channel polarization weight, a second sub-channel polarization weight, and a scaling value.
Aspect 18: The method of aspect 17, further comprising: selecting the scaling value associated with the first weighted metric from a plurality of scaling values in accordance with a quantity of the set of information bits.
Aspect 19: The method of aspect 18, wherein respective quantities of information bits correspond to respective scaling values of the plurality of scaling values.
Aspect 20: The method of any of aspects 17-19, further comprising: scaling the first sub-channel polarization weight or the second sub-channel polarization weight in accordance with the scaling value; and selecting, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.
Aspect 21: The method of any of aspects 17-20, further comprising: ordering the plurality of weighted metrics in a descending order, an initial weighted metric in the descending order of the plurality of weighted metrics being associated with a highest quality sub-channel and a final weighted metric in the descending order of the plurality of weighted metrics being associated with a lowest quality sub-channel, wherein decoding the set of information bits is associated with the descending order of the plurality of weighted metrics.
Aspect 22: The method of any of aspects 17-21, wherein each respective weighted metric from the plurality of weighted metrics is associated with a respective first sub-channel polarization weight, a respective second sub-channel polarization weight, and the scaling value.
Aspect 23: The method of any of aspects 17-22, wherein the first sub-channel polarization weight corresponds to a Gaussian approximation-based sub-channel polarization weight for a sub-channel associated with the first weighted metric and the second sub-channel polarization weight corresponds to a Reed-Muller-based sub-channel polarization weight for the sub-channel associated with the first weighted metric, and the first weighted metric is equal to a weighted sum of the Gaussian approximation-based sub-channel polarization weight and the Reed-Muller-based sub-channel polarization weight in accordance with the scaling value.
Aspect 24: The method of aspect 23, wherein the plurality of weighted metrics are associated with a hybrid construction of a polarization-adjusted convolutional code, and each respective weighted metric of the plurality of weighted metrics is associated with a respective Gaussian approximation-based sub-channel polarization weight, a respective Reed-Muller-based sub-channel polarization weight, and the scaling value in accordance with the hybrid construction.
Aspect 25: A method for wireless communication at a wireless communication device, comprising: receiving, via a set of sub-channels, a message; and decoding a set of information bits from the message in accordance with a plurality of weighted metrics, each respective weighted metric of the plurality of weighted metrics being associated with a respective sub-channel of a plurality of sub-channels, the set of sub-channels comprising at least some of the plurality of sub-channels, a first weighted metric of the plurality of weighted metrics being further associated with a first index of a first sequence, a second index of a second sequence, and a scaling value.
Aspect 26: The method of aspect 25, further comprising: selecting the scaling value associated with the first weighted metric from a plurality of scaling values in accordance with a quantity of the set of information bits.
Aspect 27: The method of aspect 26, wherein respective quantities of information bits correspond to respective scaling values of the plurality of scaling values.
Aspect 28: The method of any of aspects 25-27, further comprising: scaling the first index of the first sequence or the second index of the second sequence in accordance with the scaling value; and selecting, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.
Aspect 29: The method of any of aspects 25-28, further comprising: ordering the plurality of weighted metrics in an ascending order, an initial weighted metric in the ascending order of the plurality of weighted metrics being associated with a highest quality sub-channel and a final weighted metric in the ascending order of the plurality of weighted metrics being associated with a lowest quality sub-channel, wherein decoding the set of information bits is associated with the ascending order of the plurality of weighted metrics.
Aspect 30: The method of any of aspects 25-29, wherein each respective weighted metric from the plurality of weighted metrics is associated with a respective first index of the first sequence, a respective second index of the second sequence, and the scaling value.
Aspect 31: The method of any of aspects 25-30, wherein the first index of the first sequence corresponds to a Gaussian approximation-based sequence index for a sub-channel associated with the first weighted metric and the second index of the second sequence corresponds to a Reed-Muller-based sequence index for the sub-channel associated with the first weighted metric, and the first weighted metric is equal to a weighted sum of the Gaussian approximation-based sequence index and the Reed-Muller-based sequence index in accordance with the scaling value.
Aspect 32: The method of aspect 31, wherein the plurality of weighted metrics are associated with a hybrid construction of a polarization-adjusted convolutional code, and each respective weighted metric of the plurality of weighted metrics is associated with a respective Gaussian approximation-based sequence index, a respective Reed-Muller-based sequence index, and the scaling value in accordance with the hybrid construction.
Aspect 33: An apparatus for wireless communication at a wireless communication device, comprising a processor; memory coupled with the processor; and instructions stored in the memory and executable by the processor to cause the apparatus to perform a method of any of aspects 1-8.
Aspect 34: An apparatus for wireless communication at a wireless communication device, comprising at least one means for performing a method of any of aspects 1-8.
Aspect 35: A non-transitory computer-readable medium storing code for wireless communication at a wireless communication device, the code comprising instructions executable by a processor to perform a method of any of aspects 1-8.
Aspect 36: An apparatus for wireless communication at a wireless communication device, comprising a processor; memory coupled with the processor; and instructions stored in the memory and executable by the processor to cause the apparatus to perform a method of any of aspects 9-16.
Aspect 37: An apparatus for wireless communication at a wireless communication device, comprising at least one means for performing a method of any of aspects 9-16.
Aspect 38: A non-transitory computer-readable medium storing code for wireless communication at a wireless communication device, the code comprising instructions executable by a processor to perform a method of any of aspects 9-16.
Aspect 39: An apparatus for wireless communication at a wireless communication device, comprising a processor; memory coupled with the processor; and instructions stored in the memory and executable by the processor to cause the apparatus to perform a method of any of aspects 17-24.
Aspect 40: An apparatus for wireless communication at a wireless communication device, comprising at least one means for performing a method of any of aspects 17-24.
Aspect 41: A non-transitory computer-readable medium storing code for wireless communication at a wireless communication device, the code comprising instructions executable by a processor to perform a method of any of aspects 17-24.
Aspect 42: An apparatus for wireless communication at a wireless communication device, comprising a processor; memory coupled with the processor; and instructions stored in the memory and executable by the processor to cause the apparatus to perform a method of any of aspects 25-32.
Aspect 43: An apparatus for wireless communication at a wireless communication device, comprising at least one means for performing a method of any of aspects 25-32.
Aspect 44: A non-transitory computer-readable medium storing code for wireless communication at a wireless communication device, the code comprising instructions executable by a processor to perform a method of any of aspects 25-32.

It is noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communication systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor also may be implemented as a combination of computing devices (such as a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions also may be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (such as a list of items prefaced by a phrase such as “at least one of” or “one or more of”) indicates an inclusive list such that, for example, a list of at least one of A, B, or C means A or B or C or AB or AC or BC or ABC (A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

The term “determine” or “determining” encompasses a variety of actions and, therefore, “determining” can include calculating, computing, processing, deriving, investigating, looking up (such as via looking up in a table, a database or another data structure), or ascertaining, among other examples. Also, “determining” can include receiving (such as receiving information) or accessing (such as accessing data stored in memory), among other examples. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus for wireless communication at a wireless communication device, comprising:
a processor; and
memory coupled with the processor and storing instructions executable by the processor to cause the apparatus to:
encode a set of information bits in accordance with a plurality of weighted metrics, each respective weighted metric of the plurality of weighted metrics being associated with a respective sub-channel of a plurality of sub-channels, a first weighted metric of the plurality of weighted metrics being further associated with a first sub-channel polarization weight, a second sub-channel polarization weight, and a scaling value; and
transmit, via a set of sub-channels comprising at least some of the plurality of sub-channels, a message in accordance with encoding the set of information bits in accordance with the plurality of weighted metrics.

2. The apparatus of claim 1, wherein the instructions are further executable by the processor to cause the apparatus to select the scaling value associated with the first weighted metric from a plurality of scaling values in accordance with a quantity of the set of information bits.

3. (canceled)

4. The apparatus of claim 1, wherein the instructions are further executable by the processor to cause the apparatus to:
scale the first sub-channel polarization weight or the second sub-channel polarization weight in accordance with the scaling value; and
select, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.

5. The apparatus of claim 1, wherein the instructions are further executable by the processor to cause the apparatus to:
order the plurality of weighted metrics in a descending order, an initial weighted metric in the descending order of the plurality of weighted metrics being associated with a highest quality sub-channel and a final weighted metric in the descending order of the plurality of weighted metrics being associated with a lowest quality sub-channel, wherein encoding the set of information bits is associated with the descending order of the plurality of weighted metrics.

6. The apparatus of claim 1, wherein each respective weighted metric from the plurality of weighted metrics is associated with a respective first sub-channel polarization weight, a respective second sub-channel polarization weight, and the scaling value.

7. The apparatus of claim 1, wherein the first sub-channel polarization weight corresponds to a Gaussian approximation-based sub-channel polarization weight for a sub-channel associated with the first weighted metric and the second sub-channel polarization weight corresponds to a Reed-Muller-based sub-channel polarization weight for the sub-channel associated with the first weighted metric, and wherein the first weighted metric is equal to a weighted sum of the Gaussian approximation-based sub-channel polarization weight and the Reed-Muller-based sub-channel polarization weight in accordance with the scaling value.

8. (canceled)

9. An apparatus for wireless communication at a wireless communication device, comprising:
a processor; and
memory coupled with the processor and storing instructions executable by the processor to cause the apparatus to:
encode a set of information bits in accordance with a plurality of weighted metrics, each respective weighted metric of the plurality of weighted metrics being associated with a respective sub-channel of a plurality of sub-channels, a first weighted metric of the plurality of weighted metrics being further associated with a first index of a first sequence, a second index of a second sequence, and a scaling value; and
transmit, via a set of sub-channels comprising at least some of the plurality of sub-channels, a message in accordance with encoding the set of information bits in accordance with the plurality of weighted metrics.

10. The apparatus of claim 9, wherein the instructions are further executable by the processor to cause the apparatus to select the scaling value associated with the first weighted metric from a plurality of scaling values in accordance with a quantity of the set of information bits.

11. (canceled)

12. The apparatus of claim 9, wherein the instructions are further executable by the processor to cause the apparatus to:
scale the first index of the first sequence or the second index of the second sequence in accordance with the scaling value; and
select, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.

13. The apparatus of claim 9, wherein the instructions are further executable by the processor to cause the apparatus to:
order the plurality of weighted metrics in an ascending order, an initial weighted metric in the ascending order of the plurality of weighted metrics being associated with a highest quality sub-channel and a final weighted metric in the ascending order of the plurality of weighted metrics being associated with a lowest quality sub-channel, wherein encoding the set of information bits is associated with the ascending order of the plurality of weighted metrics.

14. The apparatus of claim 9, wherein each respective weighted metric from the plurality of weighted metrics is associated with a respective first index of the first sequence, a respective second index of the second sequence, and the scaling value.

15. The apparatus of claim 9, wherein the first index of the first sequence corresponds to a Gaussian approximation-based sequence index for a sub-channel associated with the first weighted metric and the second index of the second sequence corresponds to a Reed-Muller-based sequence index for the sub-channel associated with the first weighted metric, and wherein the first weighted metric is equal to a weighted sum of the Gaussian approximation-based sequence index and the Reed-Muller-based sequence index in accordance with the scaling value.

16. (canceled)

17. An apparatus for wireless communication at a wireless communication device, comprising:
a processor; and
memory coupled with the processor and storing instructions executable by the processor to cause the apparatus to:
receive, via a set of sub-channels, a message; and
decode a set of information bits from the message in accordance with a plurality of weighted metrics, each respective weighted metric of the plurality of weighted metrics being associated with a respective sub-channel of a plurality of sub-channels, the set of sub-channels comprising at least some of the plurality of sub-channels, a first weighted metric of the plurality of weighted metrics being further associated with a first sub-channel polarization weight, a second sub-channel polarization weight, and a scaling value.

18. The apparatus of claim 17, wherein the instructions are further executable by the processor to cause the apparatus to select the scaling value associated with the first weighted metric from a plurality of scaling values in accordance with a quantity of the set of information bits.

19. (canceled)

20. The apparatus of claim 17, wherein the instructions are further executable by the processor to cause the apparatus to:
scale the first sub-channel polarization weight or the second sub-channel polarization weight in accordance with the scaling value; and
select, in accordance with scaling the first sub-channel polarization weight or the second sub-channel polarization weight, the first weighted metric in accordance with a sum of: a scaled first sub-channel polarization weight and the second sub-channel polarization weight; or the first sub-channel polarization weight and a scaled second sub-channel polarization weight.

21. The apparatus of claim 17, wherein the instructions are further executable by the processor to cause the apparatus to:
order the plurality of weighted metrics in a descending order, an initial weighted metric in the descending order of the plurality of weighted metrics being associated with a highest quality sub-channel and a final weighted metric in the descending order of the plurality of weighted metrics being associated with a lowest quality sub-channel, wherein decoding the set of information bits is associated with the descending order of the plurality of weighted metrics.

22. (canceled)

23. (canceled)

24. (canceled)

25. An apparatus for wireless communication at a wireless communication device, comprising:
a processor; and
memory coupled with the processor and storing instructions executable by the processor to cause the apparatus to:
receive, via a set of sub-channels, a message; and
decode a set of information bits from the message in accordance with a plurality of weighted metrics, each respective weighted metric of the plurality of weighted metrics being associated with a respective sub-channel of a plurality of sub-channels, the set of sub-channels comprising at least some of the plurality of sub-channels, a first weighted metric of the plurality of weighted metrics being further associated with a first index of a first sequence, a second index of a second sequence, and a scaling value.

26. The apparatus of claim 25, wherein the instructions are further executable by the processor to cause the apparatus to select the scaling value associated with the first weighted metric from a plurality of scaling values in accordance with a quantity of the set of information bits.

27. (canceled)

28. The apparatus of claim 25, wherein the instructions are further executable by the processor to cause the apparatus to:
scale the first index of the first sequence or the second index of the second sequence in accordance with the scaling value; and
select, in accordance with scaling the first index of the first sequence or the second index of the second sequence, the first weighted metric in accordance with a sum of: a scaled first index of the first sequence and the second index of the second sequence; or the first index of the first sequence and a scaled second index of the second sequence.

29. The apparatus of claim 25, wherein the instructions are further executable by the processor to cause the apparatus to:
order the plurality of weighted metrics in an ascending order, an initial weighted metric in the ascending order of the plurality of weighted metrics being associated with a highest quality sub-channel and a final weighted metric in the ascending order of the plurality of weighted metrics being associated with a lowest quality sub-channel, wherein decoding the set of information bits is associated with the ascending order of the plurality of weighted metrics.

30. (canceled)
